(19) United States
(12) Patent Application Publication
(10) Pub. No.: US 2025/0234108 A1
(43) Pub. Date: Jul. 17, 2025

(54) IMAGE SENSOR

(71) Applicant: Samsung Electronics Co., Ltd., Suwon-si (KR)

(72) Inventor: JUNHO SEOK, Suwon-si (KR)

(21) Appl. No.: 19/018,084

(22) Filed: Jan. 13, 2025

(30) Foreign Application Priority Data
Jan. 16, 2024 (KR) 10-2024-0006964

(51) Int. Cl. H04N 25/77; H10F 39/00; H10F 39/18

(52) U.S. Cl. CPC H04N 25/77; H10F 39/18; H10F 39/802; H10F 39/8037; H10F 39/811; H10F 39/812

(57) ABSTRACT

Disclosed is an image sensor in which at least one pixel group including a plurality of pixels is arranged in a matrix form. The at least one pixel group includes at least one photoelectric conversion device, at least one floating diffusion area to which a charge of the photoelectric conversion device is transferred, at least one reset transistor that is connected to the floating diffusion area and that resets the floating diffusion area to a pixel voltage, a source follower transistor that is connected to the floating diffusion area and that outputs a pixel signal in response to a charge of the floating diffusion area, and a selection transistor that is connected to the source follower transistor and that outputs the pixel signal to an output node. A gate of the source follower transistor and the floating diffusion area are connected by a first connection line that integrally extends from the gate of the source follower transistor to the floating diffusion area as a single, unseparated body, and the first connection line makes contact with the gate of the source follower transistor and the floating diffusion area.

### CROSS-REFERENCE TO RELATED APPLICATIONS

This application claims priority under 35 U.S.C. § 119 to Korean Patent Application No. 10-2024-0006964 filed on Jan. 16, 2024, in the Korean Intellectual Property Office, the disclosures of which are incorporated by reference herein in their entireties.

### BACKGROUND

Embodiments of the present disclosure described herein relate to an image sensor.

An image sensor may convert an optical signal including image information of a subject into an electrical signal. A charge coupled device (CCD) image sensor and a complementary metal oxide semiconductor (CMOS) image sensor are widely used as an image sensor. In recent years, with the development of computer industry and communication industry, demands for image sensors with improved performance are increasing in various electronic devices such as a digital camera, a camcorder, a personal communication system (PCS), a game device, a security camera, a medical micro camera, a mobile phone, and the like.

The resolution of an image sensor may be increased by arranging more pixels in the same area. However, when a large number of pixels are disposed in the same area, there may be limitations in the physical sizes and design rules of components within the pixels (e.g., a plurality of transistors, a capacitor, and signal lines for connecting the transistors and the capacitor), and it may be difficult to make the pixels small. In particular, parasitic capacitance of adjacent signal lines within a pixel causes degradation of the image sensor. Accordingly, a technology for efficiently using the space within a pixel while minimizing defects occurring between components within the pixel is required.

### SUMMARY

Embodiments of the present disclosure provide an interconnection structure for minimizing coupling between adjacent lines in a semiconductor device and improving the degree of freedom regarding the arrangement space of lines.

Embodiments of the present disclosure provide an image sensor employing an interconnection structure for minimizing coupling between adjacent lines and improving the degree of freedom regarding the arrangement space of lines.

According to an embodiment, an image sensor includes at least one pixel group that includes a plurality of pixels and that is arranged in a matrix form. The at least one pixel group includes at least one photoelectric conversion device, at least one floating diffusion area to which a charge of the photoelectric conversion device is transferred, at least one reset transistor that is connected to the floating diffusion area and that resets the floating diffusion area to a pixel voltage, a source follower transistor that is connected to the floating diffusion area and that outputs a pixel signal in response to a charge of the floating diffusion area, and a selection transistor that is connected to the source follower transistor and that outputs the pixel signal to an output node. A gate of the source follower transistor and the floating diffusion area are connected by a first connection line that integrally extends from the gate of the source follower transistor to the floating diffusion area as a single, unseparated body, and the first connection line makes contact with the gate of the source follower transistor and the floating diffusion area.

In an embodiment of the present disclosure, a gate of each of the reset transistor, the source follower transistor, and the selection transistor may be formed of polysilicon pattern.

In an embodiment of the present disclosure, each pixel of the plurality of pixels may include ground areas, respectively, to which a ground voltage is applied, a first pixel is adjacent to a second pixel, a first ground area of the first pixel and a second ground area of the second pixel may be connected by a second connection line that extends from the first ground area toward the second ground area, and the second connection line may make contact with the first and second ground areas.

In an embodiment of the present disclosure, the image sensor may further include a semiconductor substrate, and the floating diffusion area and the first and second ground areas may each be provided as a respective active area doped with an impurity on the semiconductor substrate.

In an embodiment of the present disclosure, the image sensor may further include a first interlayer insulating film provided on the semiconductor substrate, a signal line provided on the first interlayer insulating film, and contacts that penetrate through the first interlayer insulating film and that are connected with the signal line.

In an embodiment of the present disclosure, in the pixel group, the floating diffusion area may a member of a plurality of floating diffusion areas.

In an embodiment of the present disclosure, the first connection line may connect the gate of the source follower transistor and each diffusion area of the plurality of floating diffusion areas and may be integrally formed as a single, unseparated body.

In an embodiment of the present disclosure, in the pixel group, the source follower transistor may be a member of a plurality of source follower transistors. Here, the first connection line may connect gates of each source follower transistor of the plurality of source follower transistors with the floating diffusion area and may be integrally formed as one, unseparated body.

In an embodiment of the present disclosure, the image sensor may further include a device isolation film that separates each pixel of the plurality of pixels.

In an embodiment of the present disclosure, at least a portion of the first connection line may be provided on the device isolation film and may extend in an extension direction of the device isolation film.

In an embodiment of the present disclosure, the device isolation film may be provided between the gate of the source follower transistor and the floating diffusion area.

In an embodiment of the present disclosure, the device isolation film may be provided the first ground area and the second ground area.

In an embodiment of the present disclosure, the pixel group may include first to fourth pixels having first to fourth floating diffusion areas, respectively. Alternatively, the pixel group may include first to ninth pixels having first to ninth floating diffusion areas, respectively.

In an embodiment of the present disclosure, the gate of the source follower transistor may include a polysilicon pattern.

In an embodiment of the present disclosure, the gate of the source follower transistor may be integrally formed with the first connection line as a single, unseparated body.

In an embodiment of the present disclosure, the image sensor may further include a transfer transistor that transfers a charge generated from the photoelectric conversion device to the floating diffusion area. The reset transistor may include a first reset transistor and a second reset transistor connected in series, and at least one of gates of the transfer transistor, the first reset transistor, the second reset transistor, and the selection transistor may include a polysilicon pattern.

In an embodiment of the present disclosure, an image sensor in which at least one pixel group including a plurality of pixels is arranged in a matrix form. The at least one pixel group includes at least one photoelectric conversion device, at least one floating diffusion area to which a charge of the photoelectric conversion device is transferred, at least one reset transistor connected to the floating diffusion area and configured to reset the floating diffusion area to a pixel voltage, a source follower transistor connected to the floating diffusion area and configured to output a pixel signal in response to a charge of the floating diffusion area, a selection transistor connected to the source follower transistor and configured to output the pixel signal to an output node, and a ground area provided for each of the pixels, wherein a ground voltage is applied to the ground area. A first pixel is adjacent to a second pixel, the first pixel has a first ground area, the second pixel has a second ground area, and the ground areas of first and second pixel are connected by a connection line integrally formed as a single, unseparated body. The connection line makes contact with the first and second ground.

In an embodiment of the present disclosure, an image sensor in which a pixel group including first to fourth pixels arranged in a matrix form. The pixel group includes photoelectric conversion devices provided for each of the first to fourth pixels, respectively, floating diffusion areas to which charges of the photoelectric conversion devices are transferred, first and second reset transistors connected to the floating diffusion areas and configured to reset the floating diffusion areas to a pixel voltage, a source follower transistor connected to the floating diffusion area and configured to output a pixel signal in response to a charge of the floating diffusion area, and a selection transistor connected to the source follower transistor and configured to output the pixel signal to an output node. The floating diffusion areas include first to fourth floating diffusion areas respectively provided for the first to fourth pixels. A gate of the source follower transistor and the first to fourth floating diffusion areas are connected by a connection line integrally extending from the gate of the source follower transistor to the first to fourth floating diffusion areas as a single, unseparated body. The connection line makes contact with the gate of the source follower transistor and each of the first to fourth floating diffusion areas.

### BRIEF DESCRIPTION OF THE FIGURES

The above and other objects and features of the present disclosure will become apparent by describing in detail embodiments thereof with reference to the accompanying drawings.

FIG. 1 is a plan view illustrating an example of a segment included in a semiconductor device.

FIGS. 2A, 2B, 2C, 2D, 2E, and 2F are sectional views illustrating a connection relationship between lines in the related art, where FIGS. 2A to 2F are sectional views taken along section lines A1-A1′, A2-A2′, A3-A3′, A4-A4′, A5-A5′, and A6-A6′ in FIG. 1, respectively.

FIGS. 3A, 3B, 3C, 3D, 3E, and 3F are sectional views for explaining a connection relationship between lines according to an embodiment of the present disclosure, where FIGS. 3A to 3F are sectional views taken along section lines A1-A1′, A2-A2′, A3-A3′, A4-A4′, A5-A5′, and A6-A6′ in FIG. 1, respectively.

FIGS. 4A, 4B, 4C, 4D, and 4F are sectional views for explaining a connection relationship between lines according to an embodiment of the present disclosure, where FIGS. 4A to 4F are sectional views taken along section lines A1-A1′, A2-A2′, A3-A3′, A4-A4′, A5-A5′, and A6-A6′ in FIG. 1, respectively.

FIGS. 5A, 5B, 5C, 5D, and 5E illustrate a method of manufacturing a connection line between two components according to an embodiment of the present disclosure.

FIG. 6A is a block diagram of an image sensor according to an embodiment of the present disclosure, and FIG. 6B is a circuit diagram of a pixel in the image sensor.

FIG. 7 is a plan view illustrating one pixel group of the image sensor illustrated in FIGS. 6A and 6B.

FIGS. 8A and 8B are plan views in which some of the components in FIG. 7 are omitted for convenience of description.

FIG. 9 is a sectional view taken along section line B-B′ in FIG. 7.

FIG. 10 sequentially illustrates sectional views taken along section lines B1-B1′, B2-B2′, B3-B3′, and B4-B4′ of FIG. 7.

FIG. 11 is a plan view illustrating one pixel group of an image sensor according to an embodiment of the present disclosure.

FIGS. 12A and 12B are plan views in which some of the components in FIG. 11 are omitted for convenience of description.

FIG. 13 sequentially illustrates sectional views taken along section lines C1-C1′, C2-C2′, C3-C3′, and C4-C4′ of FIG. 11.

FIG. 14 is a plan view illustrating one pixel group of an image sensor according to an embodiment of the present disclosure.

FIGS. 15A and 15B are plan views in which some of the components in FIG. 14 are omitted for convenience of description.

FIG. 16 sequentially illustrates sectional views taken along section lines B1-B1′, B2-B2′, B3-B3′, and B4-B4′ of FIG. 14.

FIG. 17 is a plan view illustrating one pixel group of an image sensor according to an embodiment of the present disclosure.

FIGS. 18A and 18B are plan views in which some of the components in FIG. 17 are omitted for convenience of description.

FIG. 19 sequentially illustrates sectional views taken along section lines B1-B1′, B2-B2′, B3-B3′, and B4-B4′ of FIG. 17.

FIGS. 20, 21, and 22 are sectional views illustrating connection relationships between lines according to embodiments of the present disclosure.

### DETAILED DESCRIPTION

Hereinafter, embodiments of the present disclosure will be described clearly and in detail to such an extent that those skilled in the art may implement the present disclosure.

The embodiments of the present disclosure will be described in more detail with reference to the accompanying drawings.

Various semiconductor devices have a circuit made up of conductive lines, also referred to hereafter simply as lines, and a plurality of transistors. The lines may be formed of conductive materials in various layers and may be interconnected in various forms. The present disclosure has an interconnection structure that minimizes the formation of parasitic capacitance between adjacent lines in the various forms of the lines.

As used herein, the phrase a “single, unseparated body” may refer to elements that are formed at the same time and of the same material, without a break in the continuity of the material of which they are formed. As one example, an element or elements that are a “single, unseparated body” may be a homogeneous monolithic element.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

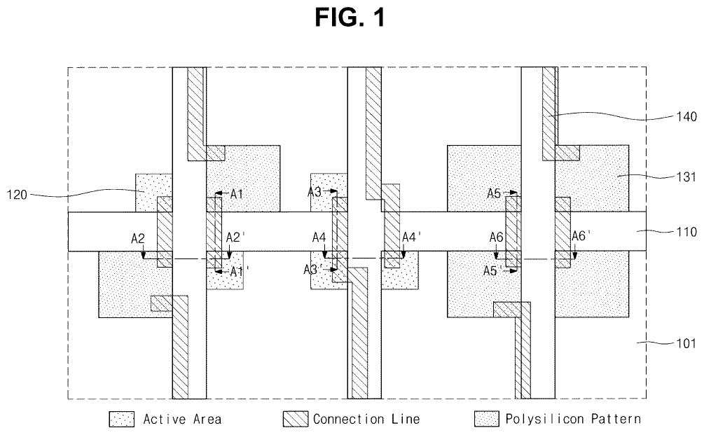

FIG. 1 is a plan view illustrating an example of a segment included in a semiconductor device.

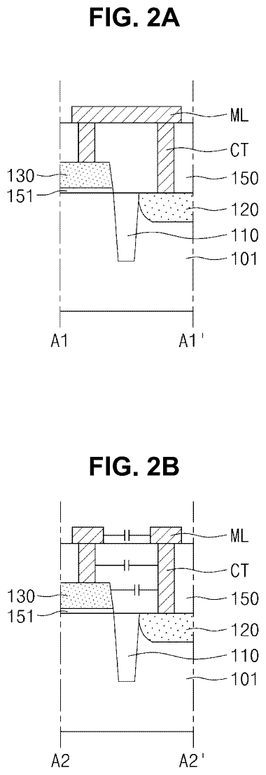

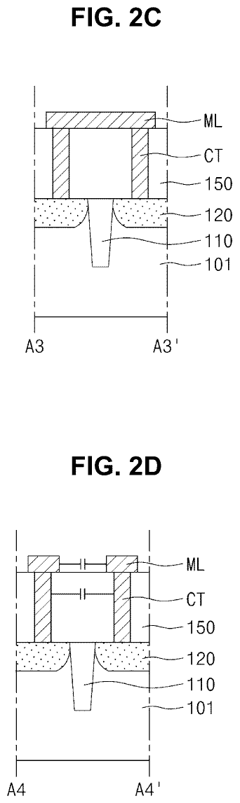

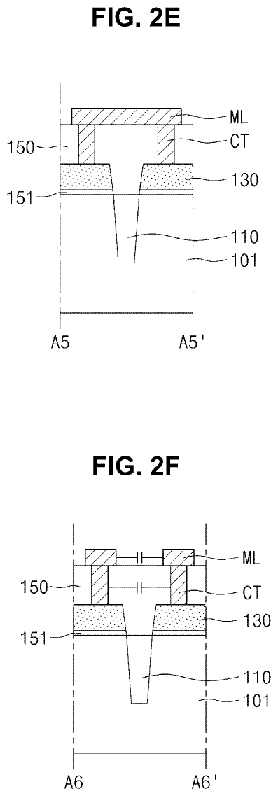

FIGS. 2A to 2F are sectional views illustrating a connection relationship between lines in the related art, where FIGS. 2A to 2F are sectional views taken along section lines A1-A1′, A2-A2′, A3-A3′, A4-A4′, A5-A5′, and A6-A6′ in FIG. 1, respectively.

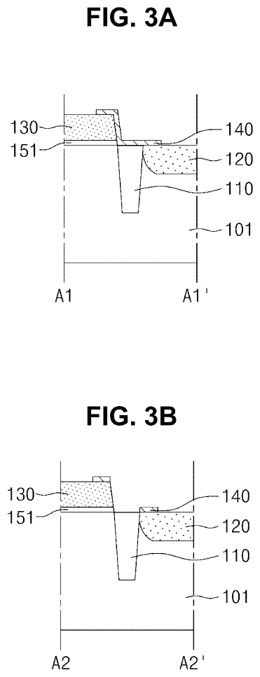

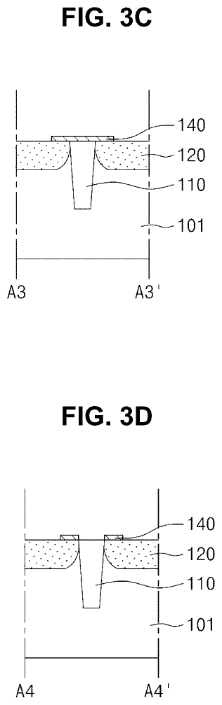

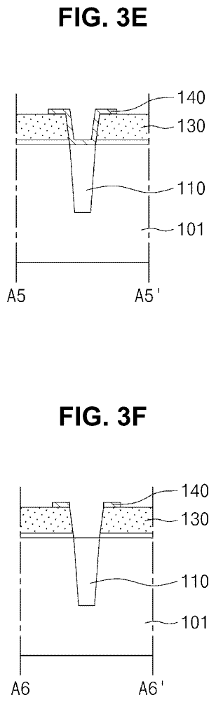

FIGS. 3A to 3F are sectional views for explaining a connection relationship between lines according to an embodiment of the present disclosure, where FIGS. 3A to 3F are sectional views taken along section lines A1-A1′, A2-A2′, A3-A3′, A4-A4′, A5-A5′, and A6-A6′ in FIG. 1, respectively.

Referring to FIGS. 1, 2A to 2F, and 3A to 3F, the semiconductor device may include a semiconductor substrate 101 and lines provided on the semiconductor substrate 101.

In this embodiment, the lines may refer to components capable of transferring charges as conductors and may include, for example, an active area 120 doped with an impurity, a polysilicon pattern 130 doped with an impurity, a signal line ML, and a contact CT for connecting components arranged with an insulating layer 150 therebetween.

The semiconductor substrate 101 corresponds to a substrate on which components of the semiconductor device are formed. For example, the semiconductor substrate 101 of FIG. 1 is a substrate on which at least a portion of pixels are formed in an image sensor and/or in which at least a portion of pixels are formed in an image sensor.

The semiconductor substrate 101 may be a silicon substrate, a germanium substrate, a silicon-germanium substrate, a Group II-VI compound semiconductor substrate, a Group III-V compound semiconductor substrate, or an SOI (silicon on insulator) substrate. The semiconductor substrate 101 may include a first conductive type impurity. Accordingly, the semiconductor substrate 101 may have a first conductive type. The first conductive type impurity may be a Group III element. For example, the first conductive type impurity may include a P-type impurity such as aluminum (Al), boron (B), indium (in), and/or gallium (Ga).

A device isolation film 110 extending from an outer surface of the semiconductor substrate 101 into the semiconductor substrate 101 may be provided inside the semiconductor substrate 101. The device isolation film 110 electrically isolates adjacent conductive components from each other and may be provided between the adjacent conductive components. For example, the device isolation film 110 may be provided between adjacent active areas 120.

The device isolation film 110 may be a deep device isolation film 110 that penetrates opposite surfaces of the semiconductor substrate 101 or may be a shallow device isolation film 110 formed only to a certain depth from one surface of the semiconductor substrate 101.

In an embodiment of the present disclosure, the device isolation film 110 may be a shallow device isolation film 110. However, without being limited thereto, the device isolation film 110 may be a deep device isolation film 110.

The active area 120 may be a portion of the semiconductor substrate 101 and may be an area doped with the first or second conductive type impurity. The active area 120 may be formed to a certain depth from the surface of the semiconductor substrate 101. The active area 120 may be used as a source or a drain of a transistor and may also be used as a ground area. In addition, the active area 120 may form various electrical junctions by a bond with a metal or another active area doped with a different conductive type impurity.

The polysilicon pattern 130 may be formed of polysilicon and may be doped with the first or second conductive type impurity. In this embodiment, the polysilicon pattern 130 may be used as a gate of the transistor and may also be used as another conductive component such as, for example, a line for transferring a signal. When the polysilicon pattern 130 is used as the gate of the transistor, a gate insulating layer 151 is provided between the polysilicon pattern 130 and the semiconductor substrate 101. The gate insulating layer 151 insulates the gate of the transistor (e.g., the polysilicon pattern 130) from the semiconductor substrate 101. The gate insulating layer 151 may include a silicon oxide layer, a silicon oxy nitride layer, a high-k dielectric layer having a higher dielectric constant than the silicon oxide layer, or a combination thereof. The high-k dielectric layer may include, for example, at least one high-k dielectric material such as metal oxide, metal oxy nitride, metal silicon oxide, or metal silicon oxy nitride, but is not limited thereto.

The active area 120 may be doped with the second conductive type impurity. In an embodiment of the present disclosure, the active area 120 may be doped with an n-type impurity.

The device isolation film 110 may be provided between the polysilicon pattern 130 and the active area 120. The device isolation film 110 may electrically isolate the polysilicon pattern 130 and the active area 120 from each other.

A polysilicon pattern 130 and an active area 120 may be electrically connected with each other in various ways to form a single node such that a signal is applied in the semiconductor device to one of the polysilicon pattern 130 or the active area 120 the same signal is present at the other of the polysilicon pattern 130 or the active area 120.

In the related art, as illustrated in FIGS. 2A to 2F, the insulating layer 150, the separate signal line ML, and the contact CT are required to connect a polysilicon pattern 130 and an active area 120 that are adjacent to each other, two active areas 120 that are adjacent to each other, and two polysilicon patterns 130 that are adjacent to each other.

For example, referring to FIG. 2A, when the polysilicon pattern 130 and the active area 120 adjacent to each other are part of the same node, the insulating layer 150 is provided on the semiconductor substrate 101, and the signal line ML for connecting the polysilicon pattern 130 and the active area 120 is provided on the insulating layer 150. The signal line ML may be connected to the polysilicon pattern 130 and the active area 120 through the contacts CT formed through the insulating layer 150 on the polysilicon pattern 130 and the active area 120.

Referring to FIG. 2B, when the polysilicon pattern 130 and the active area 120 are different nodes to which different signals are applied in the semiconductor device, the polysilicon pattern 130 and the active area 120 are spaced apart and insulated from each other without an electrical connection, although the polysilicon pattern 130 and the active area 120 are disposed close to each other. That is, a signal applied to the polysilicon pattern 130, the contact CT connected to the polysilicon pattern 130, and the signal line ML that are located on the left side of the drawing is different from a signal applied to the active area 120, the contact CT connected to the active area 120, and the signal line ML that are located on the right side of the drawing. In this case, a structure of conductor-dielectric-conductor may be present between the polysilicon pattern 130, the contact CT, and the signal line ML on the left side and the contact CT and the signal line ML on the right side. Charges may be accumulated therebetween, and parasitic capacitance may be generated therebetween.

Referring to FIG. 2C, when two active areas 120 adjacent to each other are part of the same node, the signal line ML connecting the two active areas 120 is provided on the insulating layer 150. The signal line ML may be connected to the two active areas 120 through the contacts CT formed through the insulating layer 150 on the two active areas 120.

Referring to FIG. 2D, when two active areas 120 adjacent to each other are part of different nodes to which different signals are applied in the semiconductor device, the two active areas 120 are spaced apart and insulated from each other without an electrical connection, although the two active areas 120 are disposed close to each other. That is, a signal applied to the contact CT, which is connected to the left active area 120, and the signal line ML on the left side of the drawing is different from a signal applied to the contact CT, which is connected to the right active area 120, and the signal line ML on the right side of the drawing. In this case, a structure of conductor-dielectric-conductor may be provided between the contact CT and the signal line ML on the left side and the contact CT and the signal line ML on the right side. Charges may be accumulated therebetween, and parasitic capacitance may be generated therebetween.

Referring to FIG. 2E, when two polysilicon patterns 130 adjacent to each other are part of the same node, the signal line ML connecting the two polysilicon patterns 130 is provided on the insulating layer 150. The signal line ML may be connected to the two polysilicon patterns 130 through the contacts CT formed through the insulating layer 150 on the two polysilicon patterns 130.

Referring to FIG. 2F, when two polysilicon patterns 130 adjacent to each other are part of different nodes to which different signals are applied in the semiconductor device, the two polysilicon patterns 130 are spaced apart and insulated from each other without electrical connection although the two polysilicon patterns 130 are disposed close to each other. That is, a signal applied to the contact CT, which is connected to the left polysilicon pattern 130, and the signal line ML on the left side of the drawing is different from a signal applied to the contact CT, which is connected to the right polysilicon pattern 130, and the signal line ML on the right side of the drawing. In this case, a structure of conductor-dielectric-conductor may be provided between the contact CT and the signal line ML on the left side and the contact CT and the signal line ML on the right side. Charges may be accumulated therebetween, and parasitic capacitance may be generated therebetween.

As described above, in the semiconductor device according to the related art, in order to connect the same nodes, the contacts CT extending upward from objects to be connected and the separate signal line ML connecting the contacts CT have to be additionally formed although the objects to be connected are disposed adjacent to each other in the horizontal direction parallel to the surface of the semiconductor substrate 101. However, when two components adjacent to each other are electrically connected via the contacts CT and the signal line ML, the charge transfer paths of the two adjacent components are lengthened. The increase in the charge transfer paths in the connection of the two adjacent components causes a delay of electrical signals. In addition, when components of different nodes are adjacent to each other as described above, in particular, when the contacts CT and the signal lines ML are adjacent, there is a problem in that parasitic capacitance is formed due to coupling between the different nodes.

The present disclosure minimizes a charge transfer path by using a connection line 140 without requiring a structure connected by the insulating layer 150, the contact CT, and the signal line ML, thereby reducing parasitic capacitance while preventing delay of electrical signals.

Referring to FIG. 3A, the polysilicon pattern 130 and the active area 120 adjacent to each other are directly connected by the connection line 140 such that they are a part of a single node. That is, one end of the connection line 140 makes contact with at least a portion of the upper surface and the side surface of the polysilicon pattern 130, and an opposite end of the connection line 140 makes contact with the upper surface of the active area 120. The connection line 140 is integrally formed of a conductive material as a single, unseparated body.

The connection line 140 may include various conductive materials, but is not limited thereto.

The connection line 140 may be formed of, for example, a material including a metal. When the connection line 140 includes metal, titanium, copper, tungsten, aluminum, or the like may be used. However, the present disclosure is not limited thereto, and other conductive materials, for example, various metals, organic/inorganic materials doped with an impurity, or a combination thereof may be used. The other conductive materials may include, for example, conductive metal oxide, a metal grid, a random metal network, carbon nanotubes, graphene, nanowire mesh, an ultra-thin metal film, and a conductive polymer. In an embodiment of the present disclosure, the conductive metal oxide may include indium tin oxide (ITO), indium zinc oxide (IZO), aluminum-doped zinc oxide (ZnO:Al; AZO), indium gallium zinc oxide (IGZO), fluorine-doped tin oxide, and niobium-doped anatase. The connection line 140 may be provided as a single-layer film or a multi-layer film including the aforementioned materials.

In an embodiment of the present disclosure, the connection line 140 may be formed of metal, for example, titanium or titanium/titanium nitride.

In an embodiment of the present disclosure, the material constituting the connection line 140 may be selected to have a thickness less than the thickness of the polysilicon pattern or less than the thickness of an insulating layer and the signal line in a semiconductor device in which the insulating layer and the signal line are formed. When the connection line 140 is formed of metal, the connection line 140 may have high electrical conductivity and may be subjected to patterning so as to have a thickness less than the thickness of the polysilicon pattern.

In an embodiment of the present disclosure, the polysilicon pattern 130 and the active area 120, which are two components adjacent to each other, may be directly electrically connected by the connection line 140, and therefore a separate insulating layer, a contact penetrating the insulating layer, and a signal line on the insulating layer are not required.

Referring to FIG. 3B, when the polysilicon pattern 130 and the active area 120 are each a part of different nodes to which different signals are applied in the semiconductor device, the polysilicon pattern 130 and the active area 120 are spaced apart and insulated from each other without electrical connection, although the polysilicon pattern 130 and the active area 120 are disposed close to each other. Here, since a contact or a signal line is not provided on the polysilicon pattern 130 on the left side and the active area 120 on the right side, there is no parasitic capacitance caused by adjacent contacts or signal lines. However, parasitic capacitance may be generated between the polysilicon pattern 130 on the left side and the connection line 140 on the right side and between the connection line 140 on the left side and the connection line 140 on the right side, but since the areas facing each other are very narrow when compared to that in the related art, the parasitic capacitance that actually occurs is much smaller than that in the related art. In particular, when the connection line 140 includes metal, the connection line 140 is formed to have a thickness much smaller than that of the polysilicon pattern 130, and thus, defects due to parasitic capacitance are prevented.

Referring to FIG. 3C, when the active areas 120 adjacent to each other are each part of the same node, the two adjacent active areas 120 on the semiconductor substrate 101 are electrically connected by the connection line 140 making contact with the active areas 120. One end of the connection line 140 makes contact with the upper surface of the left active area 120, and an opposite end of the connection line 140 makes contact with the upper surface of the right active area 120. The connection line 140 is integrally formed of a conductive material as a single, unseparated body.

As described above, the two active areas 120, which are two components adjacent to each other, may be directly electrically connected by the connection line 140, and therefore a separate insulating layer, a contact penetrating the insulating layer, and a signal line on the insulating layer are not required.

Referring to FIG. 3D, since a contact or a signal line is not provided on the left active area 120 and the right active area 120 as in FIG. 2D, there is no parasitic capacitance caused by adjacent contacts or signal lines. However, parasitic capacitance may be generated between the left connection line 140 and the right connection line 140, but since the areas facing each other are very narrow when compared to that in the related art, the parasitic capacitance that actually occurs is much smaller than that in the related art.

Referring to FIG. 3E, when the polysilicon patterns 130 adjacent to each other are part of the same node, the two adjacent polysilicon patterns 130 on the semiconductor substrate 101 are electrically connected by the connection line 140 making contact with the polysilicon patterns 130. That is, one end of the connection line 140 makes contact with the upper surface of the left polysilicon pattern 130, and an opposite end of the connection line 140 makes contact with the upper surface of the right polysilicon pattern 130. The connection line 140 is integrally formed of a conductive material as a single, unseparated body.

As described above, the two polysilicon patterns 130, which are two components adjacent to each other, may be directly electrically connected by the connection line 140, and therefore a separate interlayer insulating film, a contact penetrating the interlayer insulating film, and a signal line on the interlayer insulating film are not required.

Referring to FIG. 3F, since a contact or a signal line is not provided on the left polysilicon pattern 130 and the right polysilicon pattern 130 as in FIG. 2F, there is no parasitic capacitance caused by adjacent contacts or signal lines. However, parasitic capacitance may be generated between the left polysilicon pattern 130 and the right polysilicon pattern 130 and between the left connection line 140 and the right connection line 140, but since the areas facing each other are very narrow when compared to that in the related art, the parasitic capacitance that actually occurs is much smaller than that in the related art.

In the above-described embodiments, the connection line 140 may be provided when specific components on the semiconductor substrate 101 are connected, and thus an insulating layer, contacts penetrating the insulating layer, and signals lines connecting the contacts may all be omitted. Since the insulating layer, the contacts, and the signal lines are omitted, there is no parasitic capacitance caused by the contacts and the signal lines.

In addition, the places where the contacts and the signal lines would otherwise be located may be provided as spaces where other lines are installed. By omitting the insulating layer, the contacts, and the signal lines, it is possible to not only reduce the thickness of a signal wiring layer but also increase the spatial degree of freedom when lines are formed in the semiconductor device.

In an embodiment of the present disclosure, the above-described interconnection structure between the components may be modified in various forms without departing from the spirit and scope of the present disclosure. In the following embodiments, differences from the above-described embodiment will be mainly described for convenience of description and the description of elements that are the same as those described previously may be omitted or explained in brief.

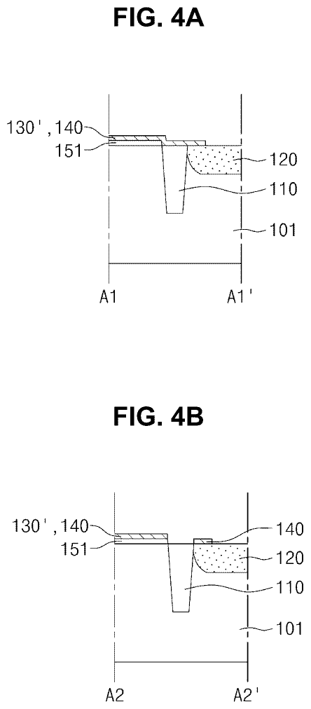

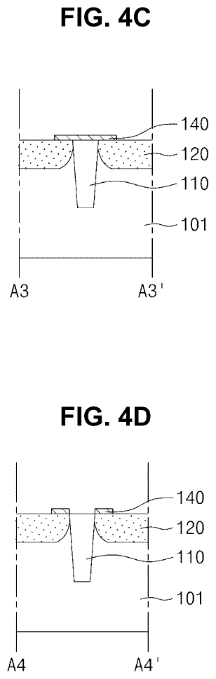

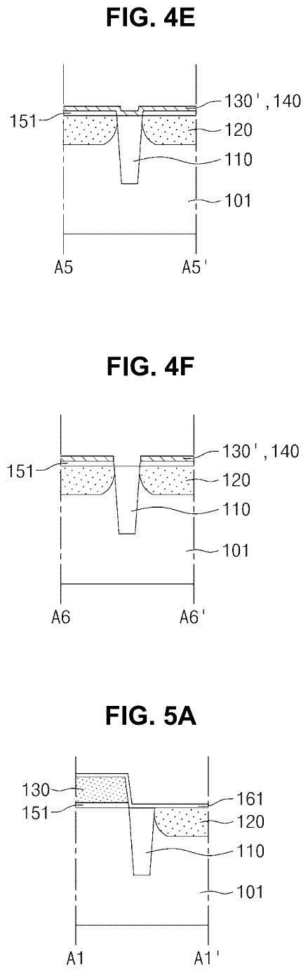

FIGS. 4A to 4F are sectional views for explaining a connection relationship between lines according to an embodiment of the present disclosure, where FIGS. 4A to 4F are sectional views taken along section lines A1-A1′, A2-A2′, A3-A3′, A4-A4′, A5-A5′, and A6-A6′ in FIG. 1, respectively.

Referring to FIGS. 4A to 4F, in a semiconductor device according to an embodiment of the present disclosure, a part of a wiring normally made of a polysilicon pattern may be formed of a connection line pattern 130′ with the polysilicon material replaced with the same material as that of the connection line 140. In this embodiment, the connection relationship illustrated in FIGS. 4A to 4F has substantially the same structure as the connection relationship between the components illustrated in FIGS. 3A and 3F, except that the polysilicon pattern part illustrated in FIGS. 3A to 3F is replaced with a connection line pattern 130′ formed of the same material as that of the connection line 140.

In an embodiment of the present disclosure, the connection line pattern 130′ may be integrally formed as a single, unseparated body with the connection line 140, and the connection line pattern 130′ and the connection line 140 may not be separately formed, but may be simultaneously formed in a single step.

In this embodiment, the connection line pattern 130′ is not formed of relatively thick polysilicon, but is integrally formed with the relatively thin connection line 140. Accordingly, parasitic capacitance between different nodes adjacent to each other is minimized. For example, as illustrated in FIGS. 4B, 4D, and 4F, the left and right connection lines 140 face each other, and parasitic capacitance caused by the left and right connection lines 140 is very insignificant because the area by which the two connection lines 140 face each other is small.

In addition, since the connection line pattern 130′ is not formed of polysilicon and is simultaneously formed of the material of the connection line 140 in a single process, a process of forming contacts and signal lines may be omitted. That is, the connection line pattern 130′ and the connection line 140 may be simultaneously formed in a single step through a single process, and thus a semiconductor device manufacturing process may be simplified.

As described above, in an embodiment of the present disclosure, the connection line makes contact with the upper surfaces of two components adjacent to each other and electrically connects the two adjacent components. The electrical connection between the two components using the connection line may be made in various ways. For example, the electrical connection may be made by the following method.

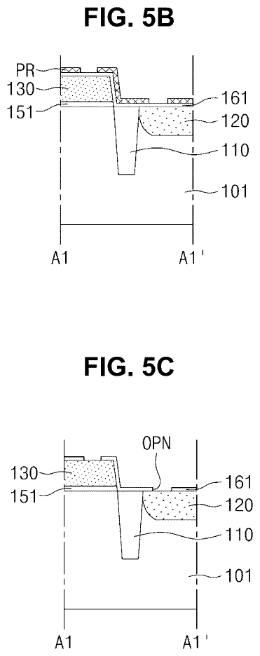

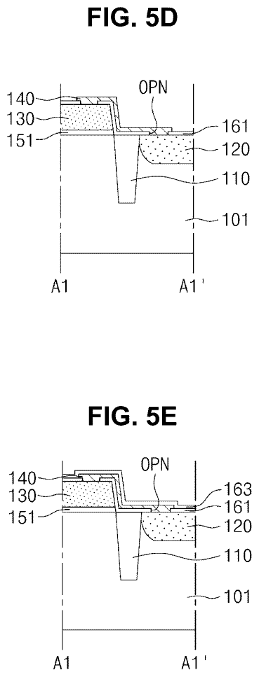

FIGS. 5A to 5D illustrate a method of manufacturing the connection line 140 between the two components according to an embodiment of the present disclosure. In FIGS. 5A to 5D, the connection relationship of the structure illustrated in FIG. 3A will be described as an example and may be applied to a connection relationship of another structure.

Referring to FIG. 5A, the semiconductor substrate 101 where the polysilicon pattern 130 and the active area 120 are formed is provided. The device isolation film 110 may be provided between the polysilicon pattern 130 and the active area 120. A first protective layer 161 is provided on the semiconductor substrate 101 where the polysilicon pattern 130 and the active area 120 are formed. The first protective layer 161 may be formed of an insulating material. When the connection line 140, which is formed at a later time, is formed of metal, the first protective layer 161 is used to prevent the metal forming the connection line 140 from penetrating into the semiconductor substrate 101. The first protective layer 161 may be formed of silicon oxide, silicon nitride, and/or silicon oxy nitride.

Referring to FIG. 5B, a photoresist pattern PR is formed on the first protective layer 161. The photoresist pattern PR may have a shape in which a portion in which the connection line 140 will make contact with the polysilicon pattern 130 and the active area 120 when the connection line 140 is formed is removed. The photoresist pattern PR may be manufactured by forming a photoresist layer, exposing the photoresist layer to light through a mask, and then developing the exposed photoresist layer.

Referring to FIG. 5C, the first protective layer 161 under the photoresist pattern is etched using the photoresist pattern as a mask. Openings OPN exposing portions of the upper surfaces of the polysilicon pattern 130 and the active area 120 under the first protective layer 161 are formed in the first protective layer 161 by etching the first protective layer 161.

Referring to FIG. 5D, the connection line 140 is formed on the first protective layer 161 having the openings OPN formed therein. The connection line 140 may be formed by forming a wiring layer with a conductive material and then patterning the wiring layer through photolithography. The above-described conductive material may be used as the conductive material forming the connection line 140. The connection line 140 makes contact with the upper surfaces of the polysilicon pattern 130 and the active area 120 through the openings OPN and electrically connects the polysilicon pattern 130 and the active area 120.

Referring to FIG. 5E, a second protective layer 163 may be formed on the semiconductor substrate 101 on which the connection line 140 is formed.

The first protective layer 161 and/or the second protective layer 163 may be formed of a material having a relatively low dielectric constant among various insulating materials. In addition, the first protective layer 161 and/or the second protective layer 163 may be formed of a material having a higher etch selectivity than the material forming the semiconductor substrate 101, for example, silicon or silicon oxide. The first protective layer 161 and/or the second protective layer 163 may include, for example, a silicon-based insulating material (e.g., Si₃N₄, SiCOH, SiO₂, SiCN, SiOCN, or the like). Alternatively, the first protective layer 161 and/or the second protective layer 163 may include a high dielectric metal oxide (e.g., hafnium oxide (HfOx), zirconium oxide (ZrO₂), titanium oxide (TiO₂), aluminum oxide (Al₂O₃, alumina), or the like).

The line connection method in the semiconductor device described above may also be employed in various semiconductor devices, for example, an image sensor. Hereinafter, an image sensor according to an embodiment of the present disclosure will be described, and then the image sensor employing the above-described connection structure will be described in detail.

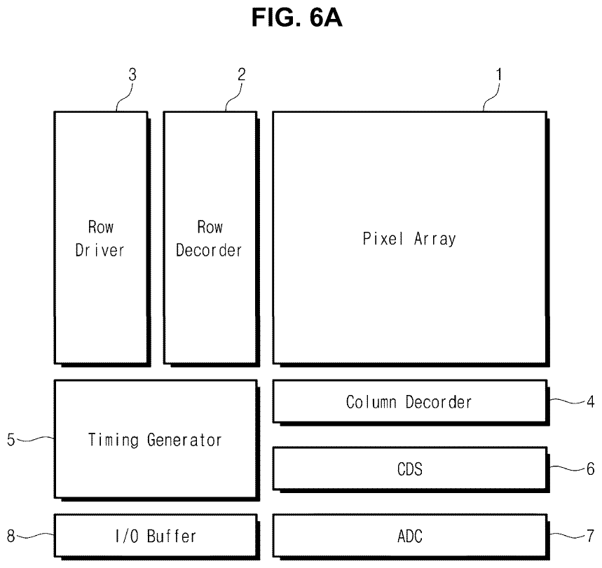

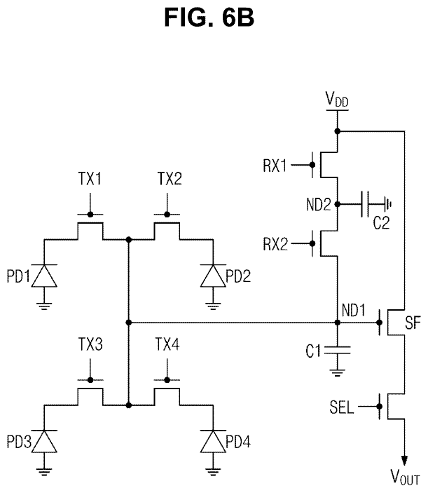

FIG. 6A is a block diagram of an image sensor according to an embodiment of the present disclosure, and FIG. 6B is a circuit diagram of a pixel in the image sensor.

Referring to FIG. 6A, the image sensor according to an embodiment of the present disclosure includes a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may be a complementary metal oxide semiconductor image sensor (CIS) that converts an optical signal into an electrical signal. The pixel array 1 may include a plurality of pixel groups arranged in two dimensions. Each pixel group may include at least one pixel and when a pixel group includes a plurality of pixels, the plurality of pixels may also be arranged in a matrix form.

The pixel array 1 may be driven by a plurality of driving signals such as a pixel selection signal, a reset signal, and a charge transfer signal from the row driver 3. In addition, the converted electrical signal is provided to the correlated double sampler 6.

The row driver 3 provides the plurality of driving signals for driving the plurality of pixels in the pixel array 1 depending on results decoded by the row decoder 2. When the pixels are arranged in a matrix form, the drive signals may be provided for respective rows.

The timing generator 5 provides a timing signal and a control signal to the row decoder 2 and the column decoder 4.

The correlated double sampler 6 receives, holds, and samples the electrical signal generated by the pixel array 1. The correlated double sampler 6 doubly samples a specific noise level and a signal level of the electrical signal and outputs a difference level corresponding to a difference between the noise level and the signal level.

The analog-to-digital converter 7 converts an analog signal corresponding to the difference level output from the correlated double sampler 6 into a digital signal and outputs the digital signal.

The input/output buffer 8 latches the digital signal. The input/output buffer 8 outputs the latched signal to an image signal processor (not illustrated) as a digital signal depending on a result decoded by the column decoder 4.

Referring to FIG. 6B, one pixel group may include at least one pixel and may include photoelectric conversion devices PD1, PD2, PD3, and PD4 and a plurality of transistors provided for each pixel.

The plurality of transistors may include a transfer transistor, a reset transistor, a source follower transistor SF, and a selection transistor SEL. In an embodiment of the present disclosure, the transfer transistor may be provided in plural numbers and may include, for example, first to fourth transfer transistors TX1, TX2, TX3, and TX4. The reset transistor may include a first reset transistor RX1 and a second reset transistor RX2.

Each of the photoelectric conversion devices PD1, PD2, PD3, and PD4 may generate charges depending on the intensity of incident light. For example, each of the photoelectric conversion devices PD1, PD2, PD3, and PD4 may be a P-N junction diode and may generate charges, that is, electrons, which are negative charges, and holes, which are positive charges, in proportion to the amount of received light. Each of the photoelectric conversion devices PD1, PD2, PD3, and PD4 may correspond to at least one of a photo transistor, a photo gate, a pinned photo diode (PPD), or a combination thereof.

In an embodiment of the present disclosure, a pixel group may include a plurality of pixels that share one floating diffusion node. In FIG. 6B, the floating diffusion node is indicated as a first node ND1. For example, the pixel group may include a plurality of pixels connected to the floating diffusion node. In an embodiment of the present disclosure, one pixel group may include one or more photoelectric conversion devices. For example, one pixel group may include two, four, or nine pixels.

In an embodiment of the present disclosure, four photoelectric conversion devices, that is, the first to fourth photoelectric conversion devices PD1, PD2, PD3, and PD4 are provided. Each of the transfer transistors TX1, TX2, TX3, and TX4 may transfer charges generated in the photoelectric conversion devices PD1, PD2, PD3, and PD4 to the first node ND1 depending on a transfer control signal.

A first capacitor C1 may store charges transferred from the photoelectric conversion devices PD1, PD2, PD3, and PD4 through the transfer transistors TX. The first capacitor C1 may be connected to the first node ND1 and may cause a voltage change by storing the transferred charges. When the capacitance value of the first capacitor C1 is small, the first capacitor C1 may store a small amount of charge, and the magnitude of the voltage change of the first node ND1 may also be small. Accordingly, when the capacitance value of the first node ND1 is small, the image sensor may operate in a high conversion gain (HCG) mode. When the capacitance value of the first capacitor C1 is large, the first capacitor C1 may store a large amount of charge, and the magnitude of the voltage change of the first node ND1 may also be large. Accordingly, when the capacitance value of the first node ND1 is large, the image sensor may operate in a low conversion gain (LCG) mode.

The source follower transistor SF may correspond to a buffer amplifier. The source follower transistor SF may be referred to as a driving transistor. Since the gate of the source follower transistor SF is connected with the first node ND1, the voltage of the first node ND1 may correspond to the gate voltage of the source follower transistor SF. That is, the source follower transistor SF may amplify the gate voltage value changed based on the charges transferred to the first node ND1 and may output a pixel signal V_{OUT}.

The drain node of the selection transistor SEL may be connected to the source node of the source follower transistor SF, and the selection transistor SF may output the pixel signal through the output node in response to the selection signal.

The first reset transistor RX1 may be connected to a power voltage node V_{DD}. The second reset transistor RX2 may be connected to the first reset transistor RX1 in series through a second node ND2. The second node ND2 may be connected with a second capacitor C2. When the second reset transistor RX2 is turned on, the first node ND1 and the second node ND2 may be connected. When the first reset transistor RX1 is turned on, the second node ND2 and a pixel voltage node may be connected.

The first reset transistor RX1 and the second reset transistor RX2 may perform a dual conversion gain (DCG) operation. For example, in the HCG mode, the first reset transistor RX1 may be turned on, and the second reset transistor RX2 may be turned off. Since the first reset transistor RX1 is turned on, the first reset transistor RX1 may be equivalent to a short circuit. Accordingly, the voltage value of the pixel voltage node may be transferred to the drain of the second reset transistor RX2. When the second reset transistor RX2 is turned on in the HCG mode, the second reset transistor RX2 may be equivalent to a short circuit. Accordingly, the first node ND1 may be sequentially reset to the voltage value of the pixel voltage node through the second reset transistor RX2 and the first reset transistor RX1.

In the LCG mode, the first reset transistor RX1 may be turned off, and the second reset transistor RX2 may be turned on. Since the second reset transistor RX2 is turned on, the second reset transistor RX2 may be equivalent to a short circuit.

When the first reset transistor RX1 is turned on in the LCG mode, charges accumulated in the first node ND1 (or, the second node ND2) may be discharged to the pixel voltage node along the first reset transistor RX1. Here, the charges accumulated in the first node ND1 (or, the second node ND2) may refer to the total sum of the charges stored in the first capacitor C1 and the second capacitor C2.

According to various embodiments, the image sensor may flexibly set the capacitance value of the floating diffusion node (e.g., the first node ND1 of the pixel group). When a high conversion gain is required, for example, when ambient illuminance is low, the image sensor may perform a reset operation only with the first node ND1 having a small capacitance value of the first capacitor C1 by turning on a reset transistor (e.g., the first reset transistor RX1) connected to the pixel voltage node and controlling the second reset transistor RX2. When a low conversion gain is required, for example, when ambient illuminance is high, the image sensor may perform a reset operation at the floating diffusion node having a high capacitance value by turning on the second reset transistor RX2 and the fourth reset transistor RG22 connected to the second node ND2, increasing the capacitance value of the first node ND1 to the total sum of the capacitances of the first capacitor C1 and the second capacitor C2, and controlling the first reset transistor RX1.

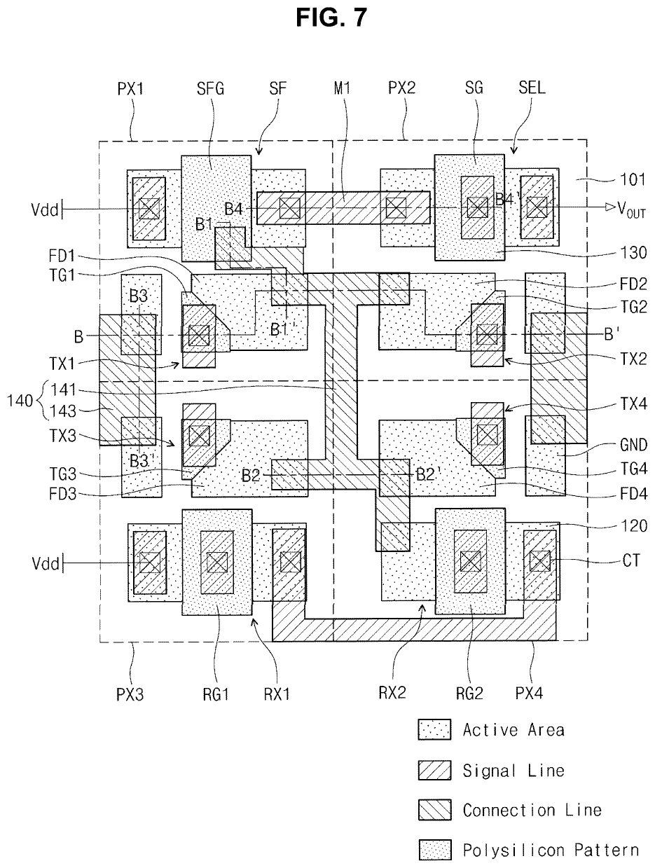

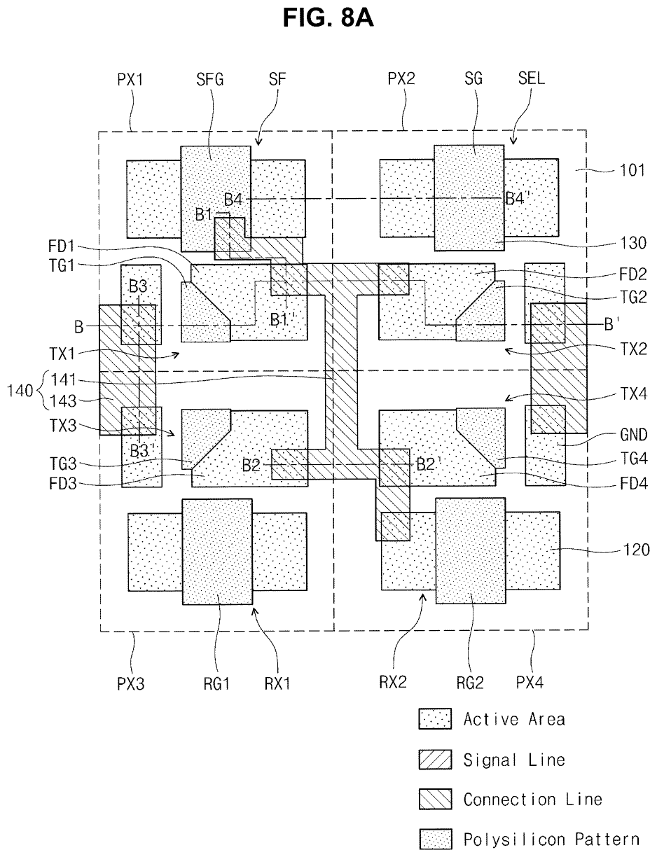

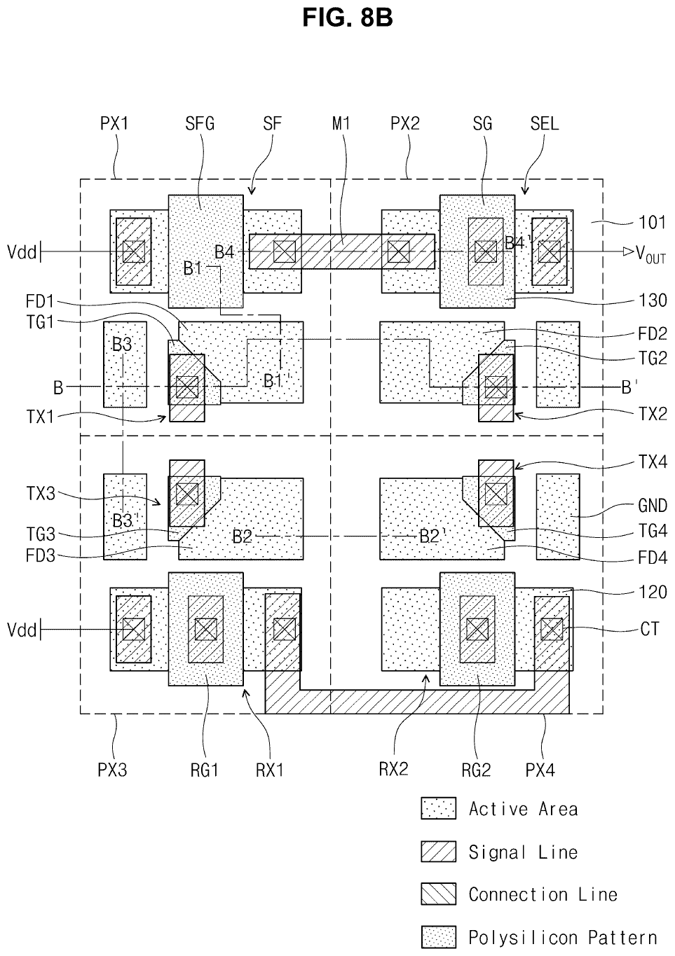

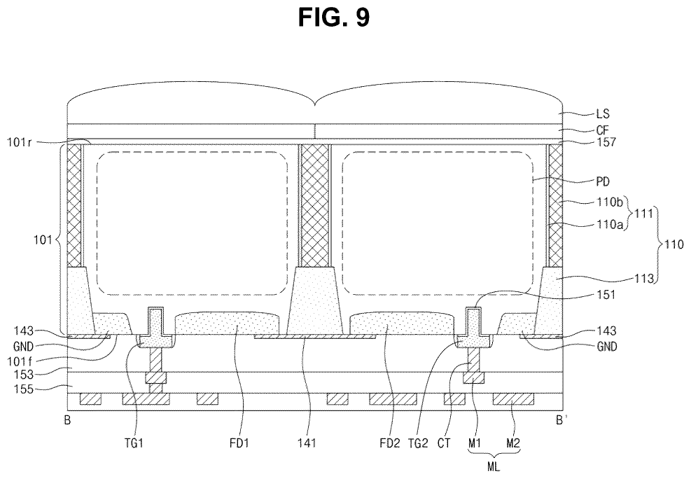

FIG. 7 is a plan view illustrating one pixel group of the image sensor illustrated in FIGS. 6A and 6B. FIGS. 8A and 8B are plan views in which some of components in FIG. 7 are omitted for convenience of description. FIG. 9 is a sectional view taken along line B-B′ in FIG. 7.

Referring to FIGS. 7, 8A, 8B, and 9, the image sensor may include a semiconductor substrate 101 and a pixel group. At least a portion of the pixel group may be provided in and/or on the semiconductor substrate 101. For example, the pixel group may include photoelectric conversion devices PD formed in the semiconductor substrate 101, at least one pixel including various lines provided in or on the semiconductor substrate 101, a device isolation film 110, a color filter CF, and a micro lens LS.

The semiconductor substrate 101 may be a silicon substrate, a germanium substrate, a silicon-germanium substrate, a Group II-VI compound semiconductor substrate, a Group III-V compound semiconductor substrate, or an SOI (silicon on insulator) substrate. The semiconductor substrate 101 may include a first conductive type impurity. Accordingly, the semiconductor substrate 101 may have a first conductive type. The first conductive type impurity may be a Group III element. For example, the first conductive type impurity may include a P-type impurity such as aluminum (Al), boron (B), indium (in), and/or gallium (Ga).

The semiconductor substrate 101 may have a front surface 101f and a rear surface 101r facing away from each other. Light may be incident to the rear surface 101r of the semiconductor substrate 101.

Lines in the pixel may be components that are implemented with conductors and that are able to transfer charges. The lines in the pixel may include an active area 120 doped with an impurity, a polysilicon pattern 130 doped with an impurity, a connection line 140, a signal line ML, and a contact CT.

In an embodiment of the present disclosure, the combination of the polysilicon pattern 130 and the active areas 120 may constitute a certain transistor. The polysilicon pattern 130 may be used as a gate of the transistor, and the active areas 120 disposed with the polysilicon pattern therebetween may be used as a source and a drain of the transistor. An active area 120 may also be used as a floating diffusion area FD or a ground area GND.

The polysilicon pattern 130 and the active areas 120 will be described in more detail as follows.

The active area 120 is a portion of the semiconductor substrate 101 and is an area doped with the first or second conductive type impurity. The active area 120 is formed to a certain depth from the surface of the semiconductor substrate 101. The active area 120 may be used as a source or drain of a transistor and may also be used as a ground area. The active area 120 may form various electrical junctions by bonding with a metal or an active area doped with a different conductive type impurity. In an embodiment of the present disclosure, first to fourth floating diffusion areas FD1, FD2, FD3, and FD4, a source and a drain of a source follower transistor SF, a source and a drain of a selection transistor SEL, sources and drains of first and second reset transistors RX1 and RX2, and ground areas GND may be formed of the active areas 120.

The polysilicon pattern 130 is doped with the first or second conductive type impurity. In this embodiment, the polysilicon pattern 130 may be used as a gate of a transistor. In an embodiment of the present disclosure, first to fourth transfer gates TG1, TG2, TG3, and TG4 of first to fourth transfer transistors TX1, TX2, TX3, and TX4, a source follower gate SFG of the source follower transistor SF, a selection gate SG of the selection transistor SEL, and first and second reset gates RG1 and RG2 of the first and second reset transistors RX1 and RX2 may be formed of the polysilicon pattern 130.

The connection line 140 connects two components that may be adjacent to each other in the pixel group, for example, the polysilicon pattern 130 and the active area 120 adjacent to each other, two active areas 120 adjacent to each other, and/or two polysilicon patterns 130 adjacent to each other.

The signal line ML is a line provided on the semiconductor substrate 101 and transfers various electrical signals of the image sensor. The signal line ML may be provided on at least one interlayer insulating film stacked on the semiconductor substrate 101.

At least one interlayer insulating film may be provided. In FIG. 9, for convenience of description, the interlayer insulating film is illustrated as including two layers, that is, a first interlayer insulating film 153 and a second interlayer insulating film 155. However, the number of interlayer insulating films is not limited thereto, and in an embodiment of the present disclosure, more interlayer insulating films may be provided.

Signal lines, for example, a first signal line M1 and a second signal line M2 may be provided in the first interlayer insulating film 153 and the second interlayer insulating film 155. A conductive path through the first and second interlayer insulating film 153 and 155 may be provided by the contact CT penetrating through the interlayer insulating film.

In an embodiment of the present disclosure, the contact CT connects the polysilicon pattern 130 (e.g., a gate of a transistor) and the active area 120 (e.g., a floating diffusion area or a ground). The polysilicon pattern 130 and the active area 120 are provided under the first interlayer insulating film 153 with a first signal line M1 on the first interlayer insulating film 153, with “under” being used in the context of towards the rear semiconductor substrate surface as being “under”. In other words, the contact CT penetrates through the first interlayer insulating film 153 and connects the polysilicon pattern 130 and/or the active area 120 to the first signal line M1. The second signal line M2 on the second interlayer insulating film 155 may be connected with the first signal line M1 on the first interlayer insulating film 153 through the contact CT formed in the second interlayer insulating film 155.

The pixels may be connected to each other or external components through the signal lines ML provided in multiple layers.

In an embodiment of the present disclosure, the transistors in the pixel group may be n-MOS transistors, and a source and a drain of each transistor (i.e., the active areas 120) may be areas doped with the second conductive type impurity, which is an n-type impurity. However, the transistors may be p-MOS transistors. Accordingly, the positions of the source and drain of each transistor may be varied.

In an embodiment of the present disclosure, as illustrated, the one pixel group may include first to fourth pixels PX1, PX2, PX3, and PX4 arranged in a 2×2 matrix. Each of the first to fourth pixels PX1, PX2, PX3, and PX4 includes a photoelectric conversion device, a floating diffusion area, and a transfer transistor. That is, the first pixel PX1 includes a photoelectric conversion device PD, the first floating diffusion area FD1, and the first transfer transistor TX1, the second pixel PX2 includes a photoelectric conversion device PD, the second floating diffusion area FD2, and the second transfer transistor TX2, the third pixel PX3 includes a photoelectric conversion device PD, the third floating diffusion area FD3, and the third transfer transistor TX3, and the fourth pixel PX4 includes a photoelectric conversion device PD, the fourth floating diffusion area FD4, and the fourth transfer transistor TX4.

In addition, the one pixel group may further include the first reset transistor RX1, the second reset transistor RX2, the source follower transistor SF, and the selection transistor SEL. Each of the first reset transistor RX1, the second reset transistor RX2, the source follower transistor SF, and the selection transistor SEL may be provided in one of the first to fourth pixels PX1, PX2, PX3, and PX4. For example, the first reset transistor RX1 may be provided in the third pixel PX3, the second reset transistor RX2 may be provided in the fourth pixel PX4, the source follower transistor SF may be provided in the first pixel PX1, and the selection transistor SEL may be provided in the second pixel PX2. In addition, in the one pixel group, one or more ground areas GND may be provided for each pixel. However, the arrangement of wiring including transistors in the one pixel group is not limited thereto and may be formed differently.

The photoelectric conversion devices PD may be provided for the respective pixels and may be interposed between the front surface 101f and the rear surface 101r of the semiconductor substrate 101. The photoelectric conversion devices PD may be doped areas containing the second conductive type impurity. In an embodiment of the present disclosure, the photoelectric conversion devices PD may include a Group V element, and the Group V element may be the second conductive type impurity. The second conductive type impurity may have a conductive type opposite to that of the first conductive type impurity. The second conductive type impurity may include an n-type impurity such as phosphorus, arsenic, bismuth, and/or antimony.

The ground area GND may be formed from an active area 120 in each pixel. The ground area GND may have the first conductive type. In some embodiments, the ground area GND may have the first conductive type with a higher impurity concentration than the semiconductor substrate 101. For example, the ground area GND may be an impurity area formed by ion implanting a high-concentration p-type impurity (p++) into the p-type semiconductor substrate 101.

The first to fourth floating diffusion areas FD1, FD2, FD3, and FD4 may each be formed from an active area 120 in the semiconductor substrate 101. The first to fourth floating diffusion areas FD1, FD2, FD3, and FD4 may be spaced apart from the photoelectric conversion device PD and the ground area GND. The first to fourth floating diffusion areas FD1, FD2, FD3, and FD4 may have the second conductive type. For example, the first to fourth floating diffusion areas FD1, FD2, FD3, FD4) may be impurity areas having the second conductive type formed by ion implanting an n-type impurity into the p-type semiconductor substrate 101.

In some embodiments, the first to fourth floating diffusion areas FD1, FD2, FD3, and FD4 may have the second conductive type with a higher impurity concentration than the photoelectric conversion device PD. For example, the floating diffusion area FD may be formed by ion implanting a high-concentration m-type impurity (n+) into the p-type semiconductor substrate 101. A channel area may be formed between the photoelectric conversion device PD and the floating diffusion area FD.

The first to fourth transfer transistors TX1, TX2, TX3, and TX4 may include, respectively, the first to fourth transfer gates TG1, TG2, TG3, and TG4, the gate insulating layer 151, and gate spacers. The first to fourth transfer gates TG1, TG2, TG3, and TG4 form a transfer channel between the photoelectric conversion devices PD and the first to fourth floating diffusion areas FD1, FD2, FD3, and FD4. The gate insulating layer 151 insulates the semiconductor substrate 101 and the first to fourth transfer gates TG1, TG2, TG3, and TG4. The gate spacers are provided on the side surfaces of the first to fourth transfer gates TG1, TG2, TG3, and TG4. The first to fourth transfer gates TG1, TG2, TG3, and TG4 may have a buried gate structure.

An interlayer insulating film may be provided on the front surface of the substrate where the first to fourth transfer gates TG1, TG2, TG3, and TG4 are formed. In an embodiment, the interlayer insulating film may be provided as a single layer or a multi-layer film. For example, the interlayer insulating film may be provided as the first and second interlayer insulating films 153 and 155. The first and second interlayer insulating films 153 and 155 may include at least one of silicon oxide, silicon nitride, silicon oxy nitride, or a low-k material having a lower dielectric constant than silicon oxide, but are not limited thereto. For example, the first interlayer insulating film 153 may include undoped silicate glass (USG), for example, tetraethyl orthosilicate (TEOS).

The device isolation film 110 may be provided between adjacent pixels to separate the pixels. In particular, pixels adjacent to each other may be separated by the device isolation film 110. For example, the device isolation film 110 may be provided along the periphery of the photoelectric conversion devices PD when viewed from above the plane.

The device isolation film 110 may include a pixel isolation film 111 surrounding the photoelectric conversion device PD when viewed from above the plane and/or a shallow device isolation film 113 provided at a shallower depth than the pixel isolation film 111.

The pixel isolation film 111 may be formed in the semiconductor substrate 101 to surround each pixel. For example, the pixel isolation film 111 may be provided in a form in which an insulating material is buried in a deep trench formed by patterning the semiconductor substrate 101. That is, the pixel isolation film 111 may be provided as a deep-trench isolation (DTI) film. The deep trench may be provided in a form that penetrates the semiconductor substrate 101. For example, the deep trench may be provided in a form that penetrates through the semiconductor substrate between the front and rear surfaces of the semiconductor substrate 101.

In an embodiment of the present disclosure, the pixel isolation film 111 may include a conductive isolation film 110b filled with a conductive material in the deep trench and an insulating liner 110a provided between the semiconductor substrate 101 and the conductive isolation film 110b. The conductive isolation film 110b may include a crystalline semiconductor material, for example, polysilicon doped with an impurity. The conductive isolation film 110b may be spaced apart from the semiconductor substrate 101 by the insulating liner 110a. Accordingly, when the image sensor operates, the conductive isolation film 110b may be electrically isolated from the semiconductor substrate 101.

The shallow device isolation film 113 is provided in a shallow trench recessed to a certain depth from the front surface. Unlike the deep trench, the shallow trench is recessed only to a certain depth from the front surface of the semiconductor substrate 101 and does not penetrate the semiconductor substrate 101. In an embodiment of the present disclosure, the shallow device isolation film 113 may be formed of multiple layers. The shallow device isolation film 113 may also include at least one of silicon oxide, silicon nitride, silicon oxy nitride, or a combination thereof, but is not limited thereto.

In an embodiment of the present disclosure, the shallow device isolation film 113 may be provided along the periphery of one pixel so as to be spaced apart from a pixel adjacent to the one pixel. However, without being limited thereto, the shallow device isolation film 113 may be provided to electrically isolate two adjacent components in one pixel. For example, the shallow device isolation film 113 may be provided between the floating diffusion area and the ground area GND adjacent to each other in one pixel to electrically insulate the floating diffusion area and the ground area. In some drawings, the device isolation film 110 is illustrated as including both the pixel isolation film 111 and the shallow device isolation film 113. However, this is for convenience of description, and the device isolation film 110 may be formed of the shallow device isolation film 113 without the pixel isolation film 111.

A rear insulating layer 157 may be provided on the rear surface 101r of the semiconductor substrate 101. The rear insulating layer 157 may cover the rear surface 101r of the semiconductor substrate 101 and may be provided in multiple layers. For example, the rear insulating layer 157 may include a silicon-based insulating material such as silicon oxide, silicon nitride, and/or silicon oxy nitride.

The color filter CF is provided on the rear insulating layer. The color filter CF may be disposed for each pixel on the rear surface 101r of the semiconductor substrate 101. For example, the color filters CF may be provided at positions corresponding to the photoelectric conversion devices PD. Each of the color filters CF may include one of a red filter, a blue filter, and a green filter. However, the present disclosure is not limited thereto, and filters of other colors may be provided. The color filters CF may form color filter arrays.

The micro lens LS may be disposed on the rear surface 101r of the semiconductor substrate 101. For example, the micro lens LS may be disposed on the color filter CF. The micro lens LS may include a lens pattern and a flat portion. The flat portion of the micro lens LS may be provided on the color filters CF. The lens pattern may be provided on the flat portion. The lens pattern may be integrally formed with the flat portion and may be connected with the flat portion without an interface. The lens pattern may include the same material as the flat portion. In another example, the flat portion may be omitted, and the lens pattern may be directly disposed on the color filters CF.

The lens pattern may have a partial hemispherical shape. The lens pattern may condense incident light. The lens pattern may be provided in a position corresponding to the photoelectric conversion devices PD of the semiconductor substrate 101. The micro lens LS may be transparent and may transmit light. The micro lens LS may include an organic material such as a polymer. For example, the micro lens LS may include a photoresist material or a thermosetting resin.

In the image sensor having the above-described structure, when lines on the semiconductor substrate 101 are connected, the lines may be interconnected using at least one connection line 140.

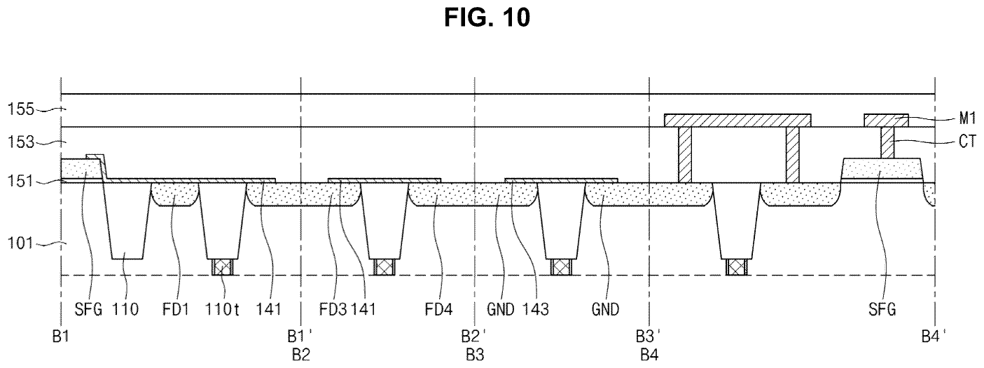

FIG. 10 illustrates sectional views taken along the section lines illustrated in FIG. 7, where FIG. 10 illustrates a connection relationship between lines of the image sensor of the present disclosure. FIG. 10 illustrates sectional views taken along section lines B1-B1′, B2-B2′, B3-B3′, and B4-B4′ of FIG. 7. Here, for convenience of description, FIG. 10 illustrates the image sensor of FIG. 7 in an inverted form (i.e., the front surface of the semiconductor substrate 101 now faces upward in the drawings).

Referring to FIGS. 7, 8A, 8B, 9, and 10, in an embodiment of the present disclosure, some of the gates, sources, and drains of the transistors, the ground areas, and the floating diffusion areas in one pixel group are connected by the connection lines 140, and the other parts are connected by the signal lines ML.

The connection lines 140 may include a first connection line 141 connecting the source follower gate SFG and at least one of the first to fourth floating diffusion areas FD1, FD2, FD3, and FD4 and a second connection line 143 connecting the adjacent ground areas GND.

One end of the first connection line 141 may make contact with the source follower gate SFG, and an opposite end of the first connection line 141 may make contact with at least one of the first to fourth floating diffusion areas FD1, FD2, FD3, and FD4. The first connection line 141 may be integrally formed as a single, unseparated body. In an embodiment of the present disclosure, the first connection line 141 may connect the source follower gate SFG and the first to fourth floating diffusion areas FD1, FD2, FD3, and FD4, and even in this case, the first connection line 141 may be integrally provided as a single, unseparated body. In addition, the first connection line 141 may make contact with the drain of the second reset transistor RX2.

In an embodiment of the present disclosure, the first to fourth floating diffusion areas FD1, FD2, FD3, and FD4 of the first to fourth pixels PX1, PX2, PX3, and PX4 may be disposed adjacent to one another. For example, the first to fourth floating diffusion areas FD1, FD2, FD3, and FD4 may be disposed at facing corners of the four pixels. Since the first to fourth floating diffusion areas FD1, FD2, FD3, and FD4 are disposed adjacent to each other, the first to fourth floating diffusion areas FD1, FD2, FD3, and FD4 may be easily connected using the first connection line 141. However, the positions of the first to fourth floating diffusion areas FD1, FD2, FD3, and FD4 are not limited thereto, and the first to fourth floating diffusion areas FD1, FD2, FD3, and FD4 may be arranged in various forms in the first to fourth pixels PX1, PX2, PX3, and PX4 as long as the first to fourth floating diffusion areas FD1, FD2, FD3, and FD4 are connected by the first connection line 141. Even though the first to fourth floating diffusion areas FD1, FD2, FD3, and FD4 are disposed at positions not adjacent to each other in the four pixels, the first to fourth floating diffusion areas FD1, FD2, FD3, and FD4 may be connected by the first connection line 141.

When the first connection line 141 connects all of the first to fourth floating diffusion areas FD1, FD2, FD3, and FD4, the first connection line 141 may include one end connected with the source follower gate SFG and a branch portion extending toward each of the floating diffusion areas FD1, FD2, FD3, and FD4. The one end portion of the first connection line 141 may make contact with the upper surface and/or the side surface of the source follower gate SFG. The branch portions of the first connection line 141 may make contact with the upper surfaces of the first to fourth floating diffusion areas FD1, FD2, FD3, and FD4 located at the ends of the branch portions. When the connection line 140 is connected with the first to fourth floating diffusion areas FD1, FD2, FD3, and FD4 from the source follower gate SFG, at least a portion of the first connection line 141 may be disposed along the periphery of the pixel. The periphery of the pixel is an area where other gates or the active areas 120 are not provided. The periphery of the pixel does not cause spatial restrictions on the arrangement of other components even though the connection line 140 is provided. The periphery of each pixel is a portion where the device isolation film 110 is provided. Accordingly, at least a portion of the first connection line 141 may overlap the device isolation film 110 when viewed from above the plane.

The second connection line 143 electrically connects ground areas GND of adjacent pixels. For example, the second connection line 143 makes contact with the ground areas GND provided in the first to fourth pixels PX1, PX2, PX3, and PX4 and electrically connects the ground areas GND. In an embodiment of the present disclosure, the ground areas GND provided in the respective pixels may be disposed adjacent to each other. For example, the ground areas GND provided in the first to fourth pixels PX1, PX2, PX3, and PX4 may be disposed at facing sides or corners of the four pixels. Since the ground areas GND of the first to fourth pixels PX1, PX2, PX3, and PX4 are disposed adjacent to each other, the ground areas GND of the first to fourth pixels PX1, PX2, PX3, and PX4 may be easily connected using the second connection line 143. However, the positions of the ground areas GND of the pixels are not limited thereto, and the ground areas GND may be arranged in various forms in the first to fourth pixels PX1, PX2, PX3, and PX4 as long as the ground areas GND are connected by the second connection line 143.

In an embodiment of the present disclosure, although not separately illustrated, the second connection line 143 may also extend along the periphery of the pixel and may be connected with the second connection line 143 of another adjacent pixel group. The periphery of the pixel is an area where other gates or the active areas 120 are not provided. The periphery of the pixel does not cause spatial restrictions on the arrangement of other components even though the connection line 140 is provided. The periphery of each pixel is a portion where the device isolation film 110 is provided. Accordingly, at least a portion of the second connection line 143 may overlap the device isolation film 110 when viewed from above the plane.

The first interlayer insulating film 153 may be provided on the semiconductor substrate 101 on which the transistors, the active areas 120, the ground areas GND, and the first and second connection lines 141 and 143 in the pixel group are provided.

The first signal lines Ml are provided on the first interlayer insulating film 153. The second interlayer insulating film 155 and the second signal line M2 may be provided on the first interlayer insulating film 153. The contacts CT penetrating the first interlayer insulating film 153 and the second interlayer insulating film 155 are provided between the first interlayer insulating film 153 and the first signal lines M1 and between the second interlayer insulating film 155 and the second signal lines M2.

The contacts CT may be provided on the gates, sources, and drains of some transistors to connect the gates, sources, and drains of the some transistors and the first and/or second signal lines M1 and/or M2. Specifically, the first and/or second signal lines M1 and/or M2 are connected to the selection gate SG through the contact CT provided on the selection gate SG. The first and/or second signal lines M1 and/or M2 are connected to the first to fourth transfer gates TG1, TG2, TG3, and TG4 through the contacts CT provided on the first to fourth transfer gates TG1, TG2, TG3, and TG4. The first and/or second signal lines M1 and/or M2 are connected to the first reset gate RG1 and the second reset gate RG2 through the contacts CT provided on the first reset gate RG1 and the second reset gate RG2.

The source of the source follower transistor SF and the drain of the selection transistor SEL are connected by the contacts CT provided on the source of the source follower transistor SF and the drain of the selection transistor SEL and the first signal line M1 connecting the contacts CT. The source of the selection transistor SEL is connected to the first and/or second signal lines M1 and/or M2 through the contact CT and outputs the pixel signal V_{OUT} to the first and/or second signal lines M1 and/or M2. The drain of the second reset transistor RX2 may be connected with the first connection line 141, and the source of the second reset transistor RX2 may be connected with the source of the first reset transistor RX1. The source of the second reset transistor RX2 and the drain of the first reset transistor RX1 may be connected through the contacts CT provided on the upper surfaces thereof and the first signal line M1 connecting the contacts CT. The first and/or second signal lines M1 and/or M2 are connected to the drain of the source follower transistor SF and the source of the first reset transistor RX1 through the contacts CT, and a power voltage V_{DD} is applied to the drain of the source follower transistor SF and the source of the first reset transistor RX1 through the first and/or second signal lines M1 and/or M2.

As described above, in the image sensor according to an embodiment of the present disclosure, the first and second connection lines 141 and 143 are used to electrically connect specific components. Unlike in the related art in which only the contacts CT and the signal line ML are used, the parasitic capacitance between adjacent components is minimized in the case of the structure in which the first and second connection lines 141 and 143 are used. In particular, the parasitic capacitance between the polysilicon pattern 130 and the active area 120 adjacent to each other, between two adjacent active areas 120, and/or between two adjacent polysilicon patterns 130 is minimized. In addition, by providing, on the semiconductor substrate 101, the first connection line 141 and/or the second connection line 143 that makes contact with certain components and connects the components, the separate contacts CT and the signal lines ML that penetrate the interlayer insulating film may be omitted.

By omitting the contacts CT and the signal lines ML when components are connected in at least a partial area, the parasitic capacitance due to the contacts CT and the signal lines ML is prevented. In addition, spaces where other lines are able to be installed are provided in the places where the contacts CT and the signal lines ML were located. In an embodiment of the present disclosure, an extra space in which other lines are able to be installed is provided by using the connection line. Accordingly, the signal wiring layer is reduced, and the spatial degree of freedom when lines are formed in the semiconductor device is increased. Signal lines disposed on another interlayer insulating film may be formed in the extra space.

In an embodiment of the present disclosure, the connection line 140 formed to make contact with the surface of the semiconductor substrate 101, such as the first connection line 141 and/or the second connection line 143, may be used to connect components that simply accumulate charges and transfer the accumulated charges, rather than signals such as a reset signal, a selection signal, and the like. For example, in an embodiment of the present disclosure, as described above, the connection line 140 may be used to connect the floating diffusion area FD or the ground area GND. However, an object to be connected by using the connection line 140 is not limited thereto.

Although it has been described that the first connection line 141 integrally connects the first to fourth floating diffusion areas FD1, FD2, FD3, and FD4, the present disclosure is not limited thereto. For example, the first to fourth floating diffusion areas may be connected using separate connection lines 140. In addition, when the first connection line 141 connects only some of the first to fourth floating diffusion areas, the unconnected floating diffusion areas may be connected through the signal line ML and the contact CT.

Although it has been described that one pixel group includes four pixels, the present disclosure is not limited thereto, and one pixel group may include various different numbers of pixels. For example, one pixel group may include two pixels or nine pixels. In the following embodiments of image sensors, a case in which one pixel group has nine pixels will be described as an example. In the following embodiments, differences from the above-described embodiment will be mainly described.

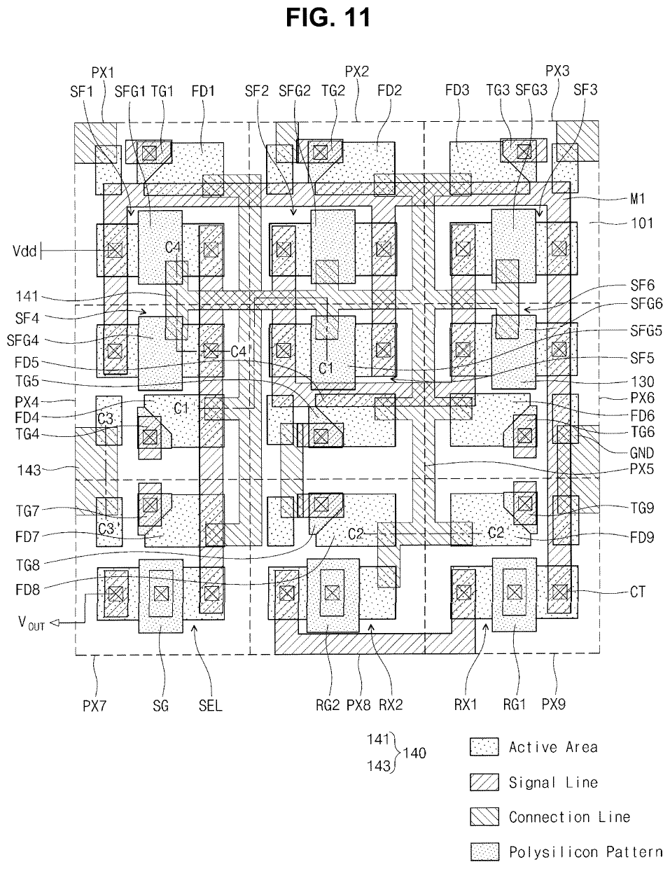

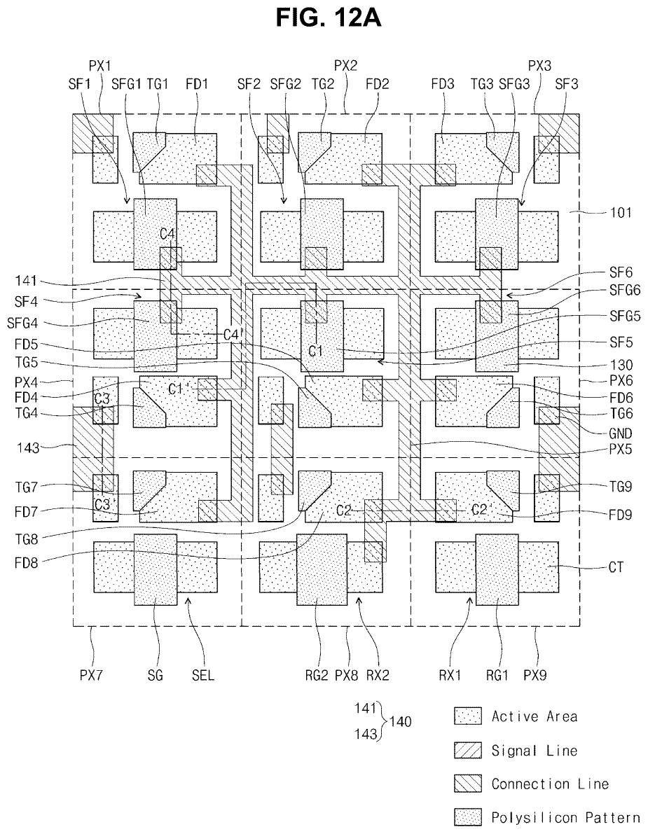

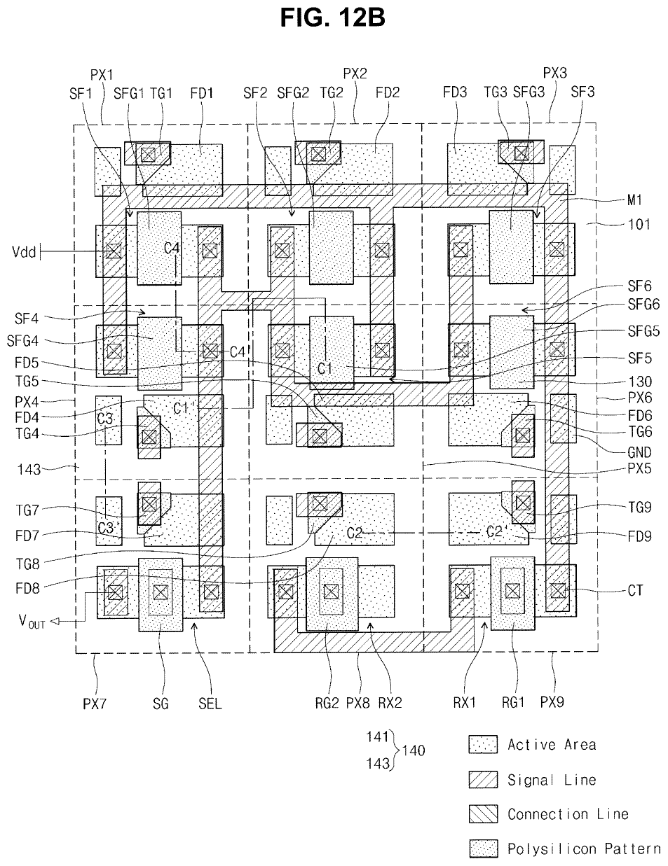

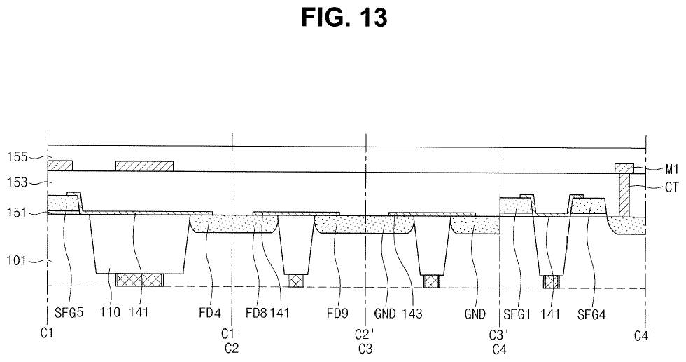

FIG. 11 is a plan view illustrating one pixel group of an image sensor according to an embodiment of the present disclosure. FIGS. 12A and 12B are plan views in which some of components in FIG. 11 are omitted for convenience of description. FIG. 13 sequentially illustrates sectional views taken along section lines C1-C1′, C2-C2′, C3-C3′, and C4-C4′ of FIG. 11.

Referring to FIGS. 11, 12A, 12B, and 13, as illustrated, one pixel group may include first to ninth pixels PX1, PX2, . . . , PX9 arranged in a 3×3 matrix. The one pixel group includes nine photoelectric conversion devices PD, first to ninth floating diffusion areas FD1, FD2, . . . , FD9, and first to ninth transfer transistors TX1, TX2, . . . , TX9.

In addition, the one pixel group may further include a first reset transistor RX1, a second reset transistor RX2, first to sixth source follower transistors SF1, SF2, . . . , SF6, and a selection transistor SEL. The first reset transistor RX1, the second reset transistor RX2, the first to ninth source follower transistors SF1, SF2, . . . , SF9, and the selection transistor SEL may each be provided in one of the first to ninth pixels PX1, PX2, . . . , PX9. For example, the first reset transistor RX1 may be provided in the ninth pixel PX9, the second reset transistor RX2 may be provided in the eighth pixel PX8, the first to sixth source follower transistors SF1, SF2, . . . , SF6 may be provided in the first to sixth pixels PX1, PX2, . . . , PX6, respectively, and the selection transistor SEL may be provided in the seventh pixel PX7. Here, the first to sixth source follower transistors SF1, SF2, . . . , SF6 may be provided in parallel, and the gates, sources, and drains may form the same node. In addition, in the one pixel group, one or more ground areas GND may be provided for each pixel. However, the arrangement of wiring including transistors in the one pixel group is not limited thereto and may be formed differently.

In an embodiment of the present disclosure, the gates, sources, and drains of the transistors, the ground areas, and the floating diffusion areas in the one pixel group may be connected by connection lines 140 and signal lines ML.

The connection lines 140 may include a first connection line 141 connecting a source follower gate SFG and at least one of the first to ninth floating diffusion areas FD1, FD2, . . . , FD9 and a second connection line 143 connecting adjacent ground areas GND.

The first connection line 141 may connect the first to ninth source follower gates SFG and the first to ninth floating diffusion regions FD1, FD2, . . . , FD9. For the connection of the first to ninth source follower gates SFG and the first to ninth floating diffusion regions FD1, FD2, . . . , FD9, the first connection line 141 may have branch portions extending toward the first to ninth source follower gates SFG and the first to ninth floating diffusion areas FD1, FD2, . . . , FD9. The first connection line 141 may make contact with the first to ninth source follower gates SFG and the first to ninth floating diffusion regions FD1, FD2, . . . , FD9 and may be integrally provided as a single, unseparated body. The first connection line 141 may make contact with the upper surfaces and/or the side surfaces of the first to ninth source follower gates SFG and may make contact with the upper surfaces of the first to ninth floating diffusion regions FD1, FD2, . . . , FD9.

The branch portions of the first connection line 141 may make contact with the upper surfaces of the first to ninth floating diffusion areas FD1, FD2, . . . , FD9 located at the ends of the branch portions. When the connection line 140 is connected with the first to ninth floating diffusion areas FD1, FD2, . . . , FD9 from the source follower gate SFG, at least a portion of the first connection line 141 may be disposed along the periphery of the pixel. The periphery of the pixel is an area where other gates or the active areas 120 are not provided. The periphery of the pixel does not cause spatial restrictions on the arrangement of other components even though the connection line 140 is provided. The periphery of each pixel is a portion where the device isolation film 110 is provided. Accordingly, at least a portion of the first connection line 141 may overlap the device isolation film 110 when viewed from above the plane.

The second connection line 143 electrically connects the ground areas GND of adjacent pixels. For example, the second connection line 143 makes contact with the ground areas GND provided in the first to ninth pixels PX1, PX2, . . . , PX9 and electrically connects the ground areas GND. In an embodiment of the present disclosure, the ground areas GND provided in the respective pixels may be disposed adjacent to each other. For example, the ground areas GND provided in the first to ninth pixels PX1, PX2, . . . , PX9 may be disposed at facing sides or corners of four pixels. Since the ground areas GND of the first to ninth pixels PX1, PX2, . . . , PX9 are disposed adjacent to each other, the ground areas GND of the first to ninth pixels PX1, PX2, . . . , PX9 may be easily connected using the second connection line 143. However, the positions of the ground areas GND of the pixels are not limited thereto, and the ground areas GND may be arranged in various forms in the first to ninth pixels PX1, PX2, . . . , PX9 as long as the ground areas GND are connected by the second connection line 143.

In an embodiment of the present disclosure, although not separately illustrated, the second connection line 143 may also extend along the periphery of the pixel and may be connected with the second connection line 143 of another adjacent pixel group. The periphery of the pixel is an area where other gates or the active areas 120 are not provided. The periphery of the pixel does not cause spatial restrictions on the arrangement of other components even though the connection line 140 is provided. The periphery of each pixel is a portion where the device isolation film 110 is provided. Accordingly, at least a portion of the second connection line 143 may overlap the device isolation film 110 when viewed from above the plane.

The first interlayer insulating film 153 may be provided on the semiconductor substrate 101 on which the transistors, the active areas 120, the ground areas GND, and the first and second connection lines 141 and 143 in the pixel group are provided.

The first signal lines M1 are provided on the first interlayer insulating film 153. The second interlayer insulating film 155 and the second signal line M2 may be provided on the first interlayer insulating film 153. The contacts CT penetrating the first interlayer insulating film 153 and the second interlayer insulating film 155 are provided between the first interlayer insulating film 153 and the first signal lines M1 and between the second interlayer insulating film 155 and the second signal lines M2.

The contacts CT may be provided on the gates, sources, and drains of some transistors to connect the gates, sources, and drains of the some transistors and the first and/or second signal lines M1 and/or M2. Specifically, the first and/or second signal lines M1 and/or M2 are connected to the selection gate SG through the contact CT provided on the selection gate SG. The first and/or second signal lines M1 and/or M2 are connected to the first to ninth transfer gates TG1, TG2, . . . , TG9 through the contacts CT provided on the first to ninth transfer gates TG1, TG2, . . . , TG9. The first and/or second signal lines M1 and/or M2 are connected to the first reset gate RG1 and the second reset gate RG2 through the contacts CT provided on the first reset gate RG1 and the second reset gate RG2.

The sources of the first to sixth source follower transistors SF1, SF2, . . . , SF6 and the drain of the selection transistor SEL are connected by the contacts CT provided on the sources of the first to sixth source follower transistors SF1, SF2, . . . , SF6 and the drain of the selection transistor SEL and the first signal line M1 connecting the contacts CT. The source of the selection transistor SEL is connected to the first and/or second signal lines M1 and/or M2 through the contact CT and outputs the pixel signal V_{OUT} to the first and/or second signal lines M1 and/or M2. The drain of the second reset transistor RX2 may be connected with the first connection line 141, and the source of the second reset transistor RX2 may be connected with the source of the first reset transistor RX1. The source of the second reset transistor RX2 and the drain of the first reset transistor RX1 may be connected through the contacts CT provided on the upper surfaces thereof and the first signal line M1 connecting the contacts CT. The first and/or second signal lines M1 and/or M2 are connected to the drains of the first to sixth source follower transistors SF1, SF2, . . . , SF6 and the source of the first reset transistor RX1 through the contacts CT, and the power voltage V_{DD} is applied to the drains of the first to sixth source follower transistors SF1, SF2, . . . , SF6 and the source of the first reset transistor RX1 through the first and/or second signal lines M1 and/or M2.

As described above, even in the image sensor according to this embodiment, the first and second connection lines 141 and 143 are used to electrically connect specific components, and thus the parasitic capacitance between adjacent components is minimized. In particular, the parasitic capacitance between the polysilicon pattern 130 and the active area 120 adjacent to each other, between two adjacent active areas 120, and/or between two adjacent polysilicon patterns 130 is minimized. In addition, by providing the first connection line 141 and/or the second connection line 143 in a process of connecting certain components, the separate contacts CT and the separate signal lines ML may be omitted. The omission of the separate contacts CT and the separate signal lines ML may not only prevent the parasitic capacitance caused by the separate contacts CT and the signal lines ML, but may also allow other lines to be installed in the places where the contacts CT and the signal lines ML were located. That is, by omitting the separate contacts CT and the separate signal lines ML, it is possible to not only reduce a signal wiring layer but also increase the spatial degree of freedom when lines are formed in the semiconductor device.

Although it has been described that when the lines including the transistors are formed in the image sensor according to the embodiment of the present disclosure, the gates of some of the transistors are made of the polysilicon pattern 130 and electrically connected with other components using the first connection line, the present disclosure is not limited thereto, and at least some of the polysilicon patterns may be made of the same material as that of the connection line 140.

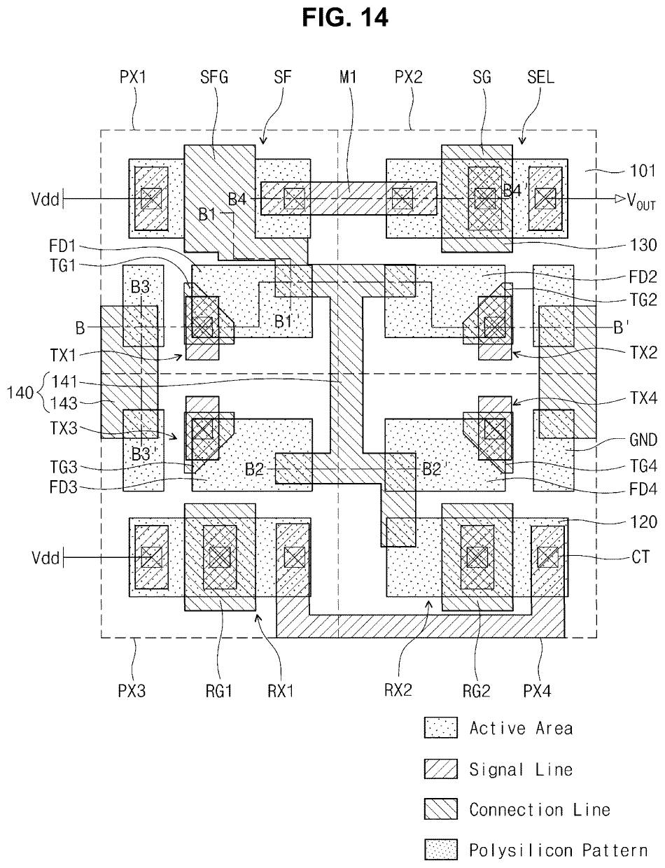

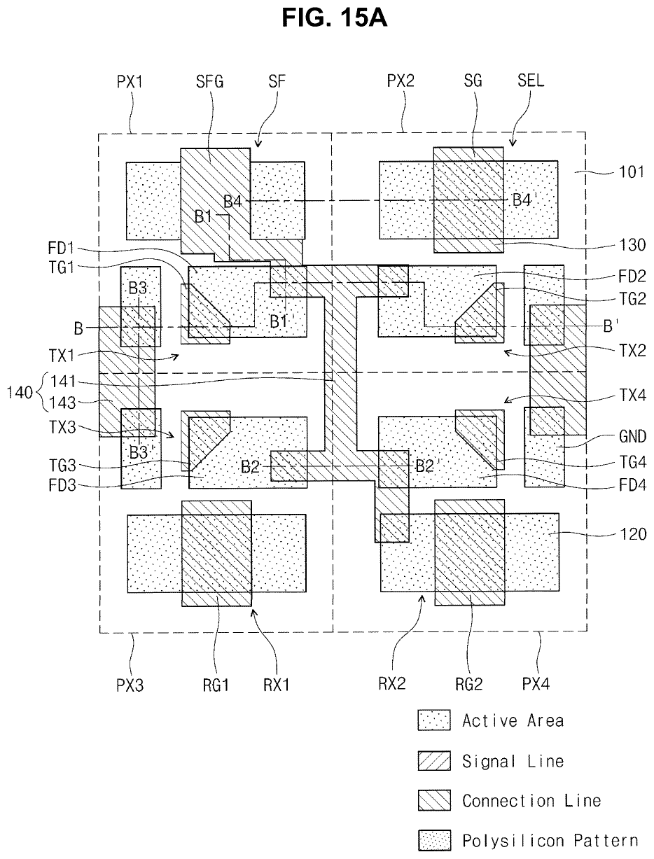

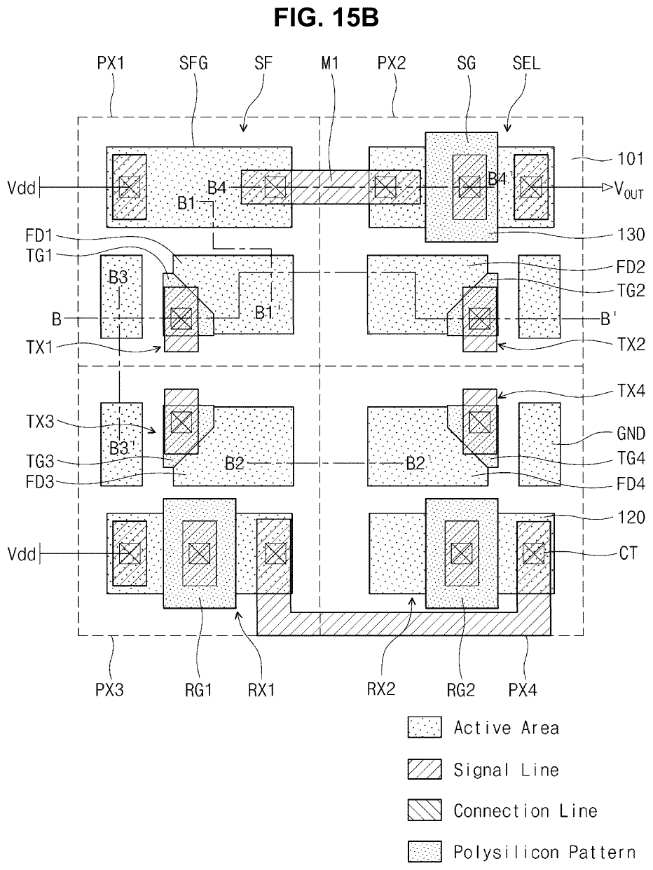

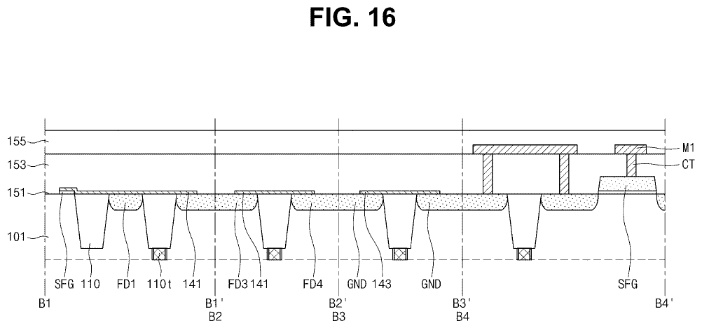

FIG. 14 is a plan view illustrating one pixel group of an image sensor according to an embodiment of the present disclosure. FIGS. 15A and 15B are plan views in which some of components in FIG. 14 are omitted for convenience of description. FIG. 16 sequentially illustrates sectional views taken along section lines B1-B1′, B2-B2′, B3-B3′, and B4-B4′ of FIG. 14.

The plan views and the sectional view illustrated in FIGS. 14, 15A, 15B, and 16 correspond to the drawings illustrated in FIGS. 7, 8A, 8B, and 10. The components are the same or substantially the same as described previously, with the exception that the gates of some of the transistors are formed of the same material as that of the connection line 140 rather than the polysilicon pattern 130. The section lines are also indicated by symbols at the same locations.

Referring to FIGS. 14, 15A, 15B, and 16, a gate of a transistor directly connected with the first connection line 141 among the transistors constituting the one pixel group of the image sensor may be made of the same material as that of the first connection line 141 rather than the polysilicon pattern 130. That is, the gate of the source follower transistor SF that makes contact with the first connection line 141 may be integrally formed as a single, unseparated body with the connection line 140. In this case, the gate of the source follower transistor SF and the connection line 140 may be simultaneously formed in a single step without being separately formed.

In this embodiment, the gate of the source follower transistor SF is not made of relatively thick polysilicon, but is integrally formed with the first connection line 141 having a relatively small thickness. Therefore, the parasitic capacitance between other adjacent nodes in the vicinity of the source follower transistor SF is minimized.

In addition, the gate of the source follower transistor SF may be formed together with the first connection line 141 in a single process the same as the formation of the first connection line 141 and thus the degree of process freedom may be increased.

In an embodiment of the present disclosure, the gates of other transistors other than the gate of the source follower transistor SF may be formed of the polysilicon pattern 130. However, embodiments of the present disclosure are not limited thereto, and the gates of the other transistors other than the gate of the source follower transistor SF may also be formed of the same material as that of the first connection line 141 or the second connection line 143 in the same process. For example, at least one of the gates of the first to fourth transfer transistors TX1, TX2, TX3, and TX4, the first reset transistor RX1, the second reset transistor RX2, and the selection transistor SEL may be formed of the material of the first connection line 141 in the same process. When the gate electrodes of the transistors are formed of the same material as that of the first connection line 141 as described above, the occurrence of parasitic capacitance with peripheral components may be minimized in the same manner as the above-described embodiments.

In the same manner, even when one pixel group includes the first to ninth pixels PX1, PX2, . . . , PX9 arranged in a 3×3 matrix, the gates of some of the transistors may be formed of the same material as that of the first connection line rather the polysilicon pattern.

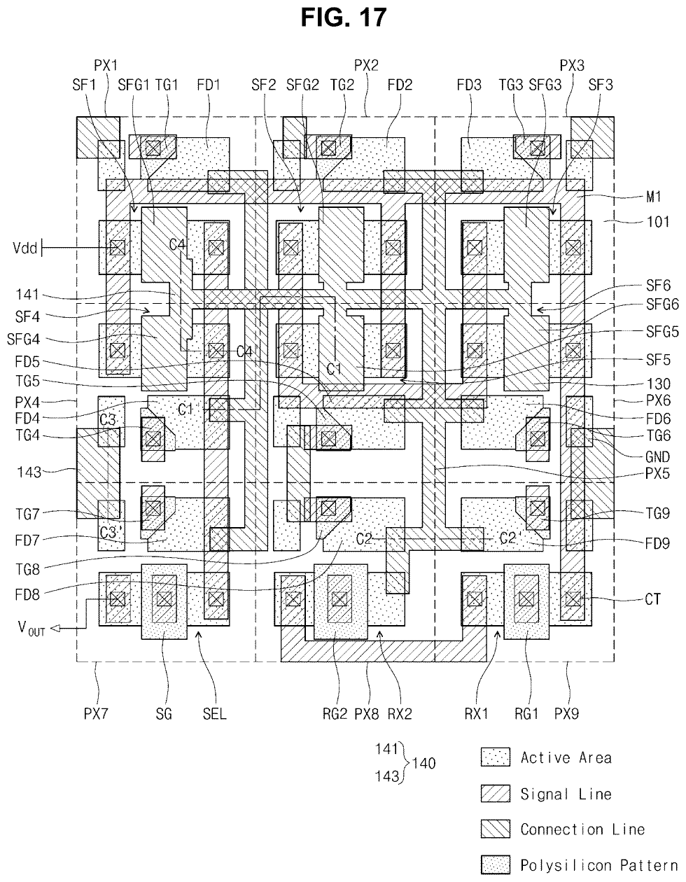

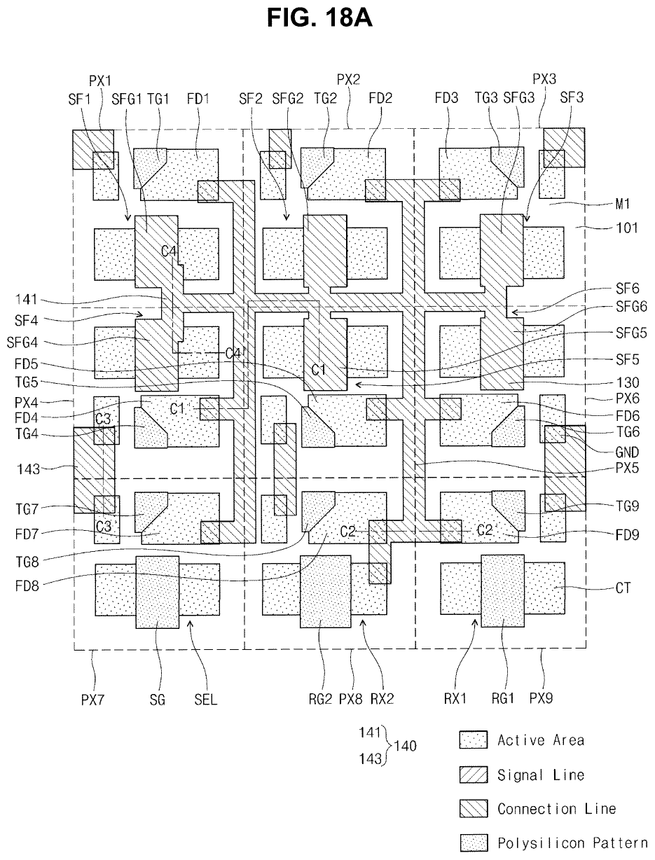

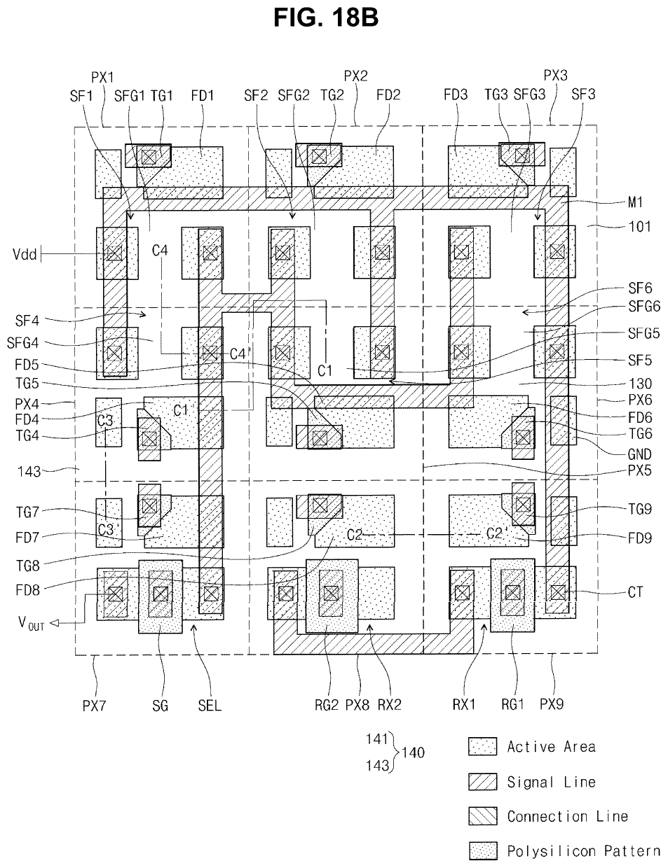

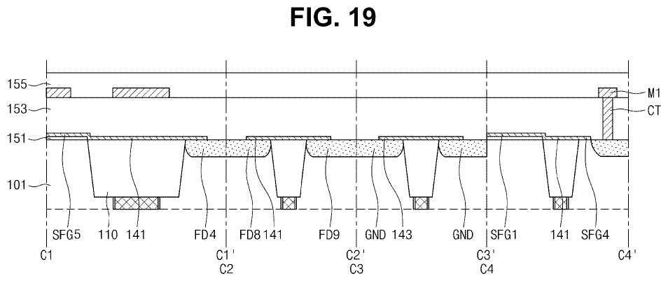

The plan views and the sectional view illustrated in FIGS. 17, 18A, 18B, and 19 correspond to the drawings illustrated in FIGS. 11, 12A, 12B, and 13. The components are the same or substantially the same as those described previously except that the gates of some of the transistors are formed of the same material as that of the connection line 140 rather than the polysilicon pattern 130.

Referring to FIGS. 17, 18A, 18B, and 19, in the one pixel group of the image sensor, a gate of a transistor directly connected with the first connection line 141 among the transistors constituting the one pixel group may be made of the same material as that of the first connection line 141 rather than the polysilicon pattern 130. That is, the gates of the first to sixth source follower transistors SF1, SF2, . . . , SF6 that make contact with the first connection line 141 may all be integrally formed as a single, unseparated body with the first connection line 141. In this case, the gates of the first to sixth source follower transistors SF1, SF2, . . . , SF6 and the connection line 140 may be simultaneously formed in a single step without being separately formed.

In this embodiment, the gate of the source follower transistor SF is not made of relatively thick polysilicon, but is integrally formed with the first connection line 141 having a relatively small thickness. Therefore, the parasitic capacitance between other adjacent nodes in the vicinity of the source follower transistor SF is minimized.

Although the connection line is used to electrically connect components in one pixel group, the present disclosure is not limited thereto, and the connection line may be used in various ways.

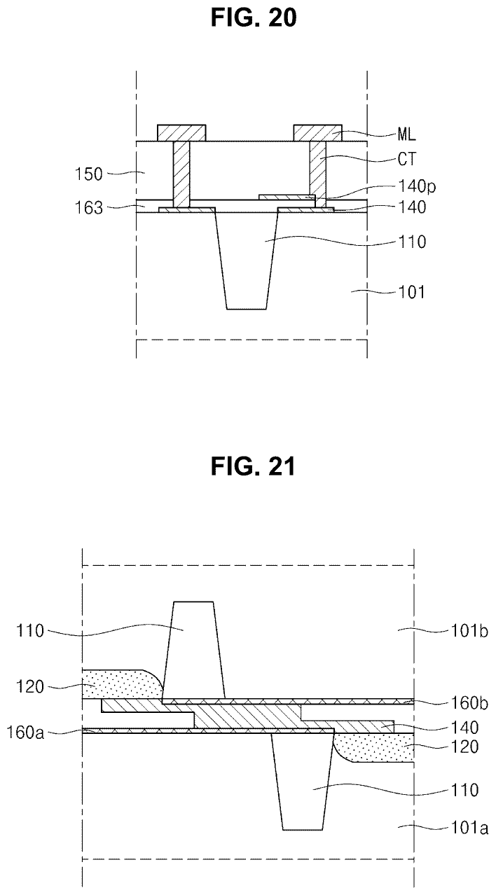

FIGS. 20 to 22 are sectional views illustrating connection relationships between lines according to embodiments of the present disclosure.

Referring to FIG. 20, after two connection lines 140 adjacent to each other with a device isolation film 110 therebetween are formed, an additional connection line 140p may be additionally formed on a second protective layer 163. As illustrated, the second protective layer 163 may be provided on the upper surfaces of the connection lines 140, and although not illustrated, a first protective layer 162 may be provided on the lower surfaces of the connection lines 140. To form the additional connection line 140p, the second protective layer 163 may be formed to be thicker than when the additional connection line 140p is not formed.

An insulating layer 150 may be provided on the additional connection line 140p, and a signal line ML may be provided on the insulating layer 150. The two adjacent connection lines 140 may be connected, or may not be connected, with the signal line ML through contacts CT. In this embodiment, the two connection lines 140 are illustrated as being connected to the signal line ML on the insulating layer 150 through the contacts CT. However, the present disclosure is not limited thereto. In an embodiment of the present disclosure, the additional connection line 140p may function as an electrode whose nodes are coupled with other components to form capacitance.

In an embodiment of the present disclosure, the additional connection line 140p may replace other signal wires ML formed on an interlayer insulating film having a multi-layer structure. Accordingly, it is possible to move and form other signal lines ML formed on an interlayer insulating film of another layer, and it is possible to additionally reduce the layer where the signal lines ML are formed.

Referring to FIG. 21, according to an embodiment of the present disclosure, it is possible to form a stack structure of adjacent semiconductor substrates 101 using only a connection line 140 without an additional signal line ML. When the two adjacent semiconductor substrates 101 are arranged to face each other and vertically stacked as illustrated, a process is required to electrically connect components on the lower side to components on the upper side.

The two semiconductor substrates vertically stacked are referred to as first and second semiconductor substrates 101a and 101b. In the related art, to connect the lower components and the upper components, a signal line is formed between the first semiconductor substrate and the second semiconductor substrate. In this case, insulating layers are formed on the first semiconductor substrate and the second semiconductor substrate, and the components of the first semiconductor substrate and the components of the second semiconductor substrate are connected through contacts.

However, in an embodiment of the present disclosure, the first semiconductor substrate 101a and the second semiconductor substrate 101b are simply connected by forming, on the first and second semiconductor substrates 101a and 101b, first and second protective layers 160a and 160b having openings in parts to be connected and placing the connection line 140 between the first and second protective layers 160a and 160b. In this case, even when the two semiconductor substrates are stacked, the components within the two semiconductor substrates may be electrically connected using only one connection line, and an effect of reducing resistance may be obtained due to an increase in the contact area between the connection line 140 and the components of the two semiconductor substrates 101a and 101b.

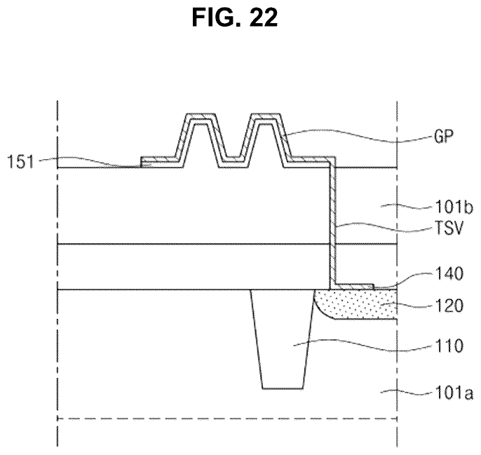

Referring to FIG. 22, when a plurality of semiconductor substrates are stacked, a connection line 140 may be used to connect the two stacked semiconductor substrates. The connection line 140 may be formed in the form of a VIA penetrating the semiconductor substrate.

As illustrated in FIG. 22, when the two adjacent semiconductor substrates are vertically stacked in the state of being disposed so as not to face each other, a process of electrically connecting components on the upper side with components on the lower side may be required.

The two semiconductor substrates vertically stacked are referred to as a first semiconductor substrate 101a and a second semiconductor substrate 101b. A through-VIA TSV may be formed through the second semiconductor substrate 101b. Gate patterns GP of various devices, for example, transistors, may be provided on the upper surface of the second semiconductor substrate 101b.

In an embodiment of the present disclosure, the connection line 140 may make contact with the gate on the second semiconductor substrate 101b and an active area 120 of the first semiconductor substrate 101a to electrically connect the gate on the second semiconductor substrate 101b and the active area 120 of the first semiconductor substrate 101a. In this case, the gate pattern GP on the second semiconductor substrate 101b may be a FinFET type gate. In addition, the gate pattern GP on the second semiconductor substrate 101b may be formed of the same material as that of the connection line 140 rather than a polysilicon pattern in the same process.

In the structure in which the components of the first and second semiconductor substrates 101a and 101b are connected by the connection line 140 through the through-VIA TSV, a separate signal line is not formed, and thus part of a photolithography process using a mask may be omitted. In addition, when the gate pattern GP is formed of a material that forms the connection line 140, such as metal, rather than a polysilicon pattern, a process of forming the polysilicon pattern 130 may be omitted, and thus the process may be simplified.

The present disclosure provides the interconnection structure that minimizes the coupling between the adjacent lines in the semiconductor device and improves the degree of freedom regarding the arrangement space of the lines.

The present disclosure provides the image sensor employing the interconnection structure that minimizes the coupling between the adjacent lines and improves the degree of freedom regarding the arrangement space of the lines.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An image sensor in which at least one pixel group including a plurality of pixels is arranged in a matrix form, wherein the at least one pixel group includes:
at least one photoelectric conversion device;
at least one floating diffusion area to which a charge of the photoelectric conversion device is transferred;
at least one reset transistor connected to the floating diffusion area and configured to reset the floating diffusion area to a pixel voltage;
a source follower transistor connected to the floating diffusion area and configured to output a pixel signal in response to a charge of the floating diffusion area; and
a selection transistor connected to the source follower transistor and configured to output the pixel signal to an output node,
wherein a gate of the source follower transistor and the floating diffusion area are connected by a first connection line configured to integrally extend from the gate of the source follower transistor to the floating diffusion area as a single, unseparated body, and the first connection line makes contact with the gate of the source follower transistor and the floating diffusion area.

2. The image sensor of claim 1, wherein a gate of each of the reset transistor, the source follower transistor, and the selection transistor is formed of polysilicon pattern.

3. The image sensor of claim 1, wherein
each pixel of the plurality of pixels includes a ground area, respectively, to which a ground voltage is applied,
a first pixel is adjacent to a second pixel, a first ground area of the first pixel and a second ground area of the second pixel are connected by a second connection line configured to extend from the first ground area toward the second ground area, and the second connection line makes contact with the first and second ground areas.

4. The image sensor of claim 3, further comprising:
a semiconductor substrate,
wherein the floating diffusion area and the first and second ground areas are each provided as a respective active area doped with an impurity on the semiconductor substrate.

5. The image sensor of claim 4, further comprising:
a first interlayer insulating film provided on the semiconductor substrate;
a signal line provided on the first interlayer insulating film; and
contacts penetrating through the first interlayer insulating film and connected with the signal line.

6. The image sensor of claim 3, wherein in the pixel group, the floating diffusion area is a member of a plurality of floating diffusion areas.

7. The image sensor of claim 6, wherein the first connection line connects the gate of the source follower transistor and each floating diffusion area of the plurality of floating diffusion areas and is integrally formed as a single, unseparated body.

8. The image sensor of claim 3, wherein in the pixel group, the source follower transistor is a member of a plurality of source follower transistors.

9. The image sensor of claim 8, wherein the first connection line connects gates of each source follower transistor of the plurality of source follower transistors with the floating diffusion area and is integrally formed as a single, unseparated body.

10. The image sensor of claim 3, further comprising:
a device isolation film configured to separate each pixel of the plurality of pixels.

11. The image sensor of claim 10, wherein at least a portion of the first connection line is provided on the device isolation film and extends in an extension direction of the device isolation film.

12. The image sensor of claim 11, wherein the device isolation film is provided between the gate of the source follower transistor and the floating diffusion area.

13. The image sensor of claim 11, wherein the device isolation film is provided between the first ground area and the second ground area.

14. The image sensor of claim 1, wherein the pixel group includes first to fourth pixels having first to fourth floating diffusion areas, respectively.

15. The image sensor of claim 1, wherein the pixel group includes first to ninth pixels having first to ninth floating diffusion areas, respectively.

16. The image sensor of claim 1, wherein the gate of the source follower transistor includes a polysilicon pattern.

17. The image sensor of claim 1, wherein the gate of the source follower transistor is integrally formed with the first connection line as a single, unseparated body.

18. The image sensor of claim 17, further comprising:
a transfer transistor configured to transfer a charge generated from the photoelectric conversion device to the floating diffusion area,
wherein the reset transistor includes a first reset transistor and a second reset transistor connected in series, and
wherein at least one gate of the transfer transistor, the first reset transistor, the second reset transistor, or the selection transistor includes a polysilicon pattern.

19. An image sensor in which at least one pixel group including a plurality of pixels is arranged in a matrix form, wherein the at least one pixel group includes:
at least one photoelectric conversion device;
at least one floating diffusion area to which a charge of the photoelectric conversion device is transferred;
at least one reset transistor connected to the floating diffusion area and configured to reset the floating diffusion area to a pixel voltage;
a source follower transistor connected to the floating diffusion area and configured to output a pixel signal in response to a charge of the floating diffusion area;
a selection transistor connected to the source follower transistor and configured to output the pixel signal to an output node; and
a ground area provided for each of the pixels, wherein a ground voltage is applied to the ground area,
wherein a first pixel is adjacent to a second pixel, the first pixel has a first ground area, the second pixel has a second ground area, and the ground areas of first and second pixel are connected by a connection line integrally formed as a single, unseparated body, and the connection line makes contact with the first and second ground.

20. An image sensor in which a pixel group including first to fourth pixels is arranged in a matrix form, wherein the pixel group includes:
photoelectric conversion devices provided for each of the first to fourth pixels, respectively;
floating diffusion areas to which charges of the photoelectric conversion devices are transferred;
first and second reset transistors connected to the floating diffusion areas and configured to reset the floating diffusion areas to a pixel voltage;
a source follower transistor connected to the floating diffusion area and configured to output a pixel signal in response to a charge of the floating diffusion area; and
a selection transistor connected to the source follower transistor and configured to output the pixel signal to an output node,
wherein the floating diffusion areas include first to fourth floating diffusion areas respectively provided for the first to fourth pixels, a gate of the source follower transistor and the first to fourth floating diffusion areas are connected by a connection line integrally extending from the gate of the source follower transistor to the first to fourth floating diffusion areas as a single, unseparated body, and the connection line makes contact with the gate of the source follower transistor and each of the first to fourth floating diffusion areas.
